(19) United States
(12) Patent Application Publication
(10) Pub. No.: US 2025/0323018 A1
(43) Pub. Date: Oct. 16, 2025

(54) Ion Energy Distribution Control Over Substrate Edge with Non-Sinusoidal Voltage Source

(71) Applicant: Lam Research Corporation, Fremont, CA (US)

(72) Inventors: Myeong Yeol Choi, Campbell, CA (US); Ying Wu, Livermore, CA (US); Michael John Martin, Union City, CA (US); Alexander Miller Paterson, San Jose, CA (US)

(21) Appl. No.: 18/866,009

(22) PCT Filed: May 16, 2023
(86) PCT No.: PCT/US2023/022436

§ 371 Date: Nov. 14, 2024

Related U.S. Application Data
(60) Provisional application No. 63/343,082, filed on May 17, 2022.

(51) Int. Cl. H01J 37/32

(52) U.S. Cl. CPC H01J 37/32146; H01J 37/32642

(57) ABSTRACT

A bias voltage supply system includes a primary bias electrode disposed below a substrate support surface. The primary bias electrode controls a voltage on a top surface of a substrate present on the substrate support surface. The bias voltage supply system includes an edge ring electrode disposed within an edge ring that circumscribes the substrate support surface. The edge ring electrode controls a voltage on a top surface of the edge ring. The bias voltage supply system includes a voltage supply system that generates a prescribed voltage waveform as a function of time on a bias voltage supply node. A first branch circuit electrically connects the bias voltage supply node and the primary bias electrode. A second branch circuit electrically connects the bias voltage supply node and the edge ring electrode. The second branch circuit includes a series capacitor and a shunt capacitor.

### BACKGROUND

Plasma processing systems are used to manufacture semiconductor devices, e.g., chips/die, on semiconductor wafers. In the plasma processing system, the semiconductor wafer is exposed to various types of plasma to cause prescribed changes to a condition of the semiconductor wafer, such as through material deposition and/or material removal and/or material implantation and/or material modification, etc. During plasma processing of the semiconductor wafer, radiofrequency (RF) power is transmitted through a process gas within a chamber to transform the process gas into the plasma in exposure to the semiconductor wafer. Reactive constituents of the plasma, such as radicals and ions, interact with materials on the semiconductor wafer to achieve a prescribed effect on the semiconductor wafer. In some plasma processing systems, bias voltage is applied at a level of the semiconductor wafer to attract charged constituents within the plasma toward the semiconductor wafer.

As the semiconductor industry continues to move toward reduced chip size and improved chip performance, it is necessary to use more high-density and high-aspect ratio features to define transistors on the chip, which leads to transistors being more sensitive to fabrication process variations. With shrinking on-chip feature sizes, some fabrication process variations of just a few atoms may necessitate improvement in etch uniformity control. Uniform ion fluxes at the extreme edge of the semiconductor wafer, e.g., within about 5 millimeters (mm) from the edge, is a demanding requirement for plasma etching and deposition for microelectronics fabrication. Also, achievement of substantially uniform ion flux at the edge of the semiconductor wafer is a meaningful challenge because approximately 10% of the die on the substrate are impacted by fabrication process results that occur within a radial distance of about 5 mm from the outer peripheral edge of the semiconductor wafer. Non-uniformity in fabrication process results near the outer peripheral edge of the semiconductor wafer can occur because of structural, temporal, and/or electrical discontinuities around the periphery of the semiconductor wafer. It is within this context that various embodiments described herein arise.

### SUMMARY

In an example embodiment, a bias voltage supply system is disclosed. The bias voltage supply system includes a primary bias electrode disposed below a substrate support surface. The primary bias electrode is configured to control a voltage on a top surface of a substrate when present on the substrate support surface. The bias voltage supply system also includes an edge ring electrode disposed within an edge ring that circumscribes the substrate support surface. The edge ring electrode is configured to control a voltage on a top surface of the edge ring. The bias voltage supply system also includes a voltage supply system configured to generate a prescribed voltage waveform as a function of time on a bias voltage supply node. The bias voltage supply system also includes a first branch circuit electrically connected between the bias voltage supply node and the primary bias electrode. The bias voltage supply system also includes a second branch circuit electrically connected between the bias voltage supply node and the edge ring electrode. The second branch circuit includes a series capacitor and a shunt capacitor.

In an example embodiment, a bias voltage supply system is disclosed. The bias voltage supply system includes a primary bias electrode disposed below a substrate support surface. The primary bias electrode is configured to control a voltage on a top surface of a substrate when present on the substrate support surface. The bias voltage supply system also includes an edge ring electrode disposed within an edge ring that circumscribes the substrate support surface. The edge ring electrode is configured to control a voltage on a top surface of the edge ring. The bias voltage supply system also includes a first voltage supply system configured to generate a first prescribed voltage waveform as a function of time on the primary bias electrode. The first voltage supply system includes a first voltage supply and a second voltage supply. The first voltage supply is configured to generate a first temporally constant voltage magnitude. The second voltage supply is configured to generate a first temporally varying voltage. The first temporally constant voltage magnitude and the first temporally varying voltage combine to form the first prescribed voltage waveform. The bias voltage supply system also includes a second voltage supply system configured to generate a second prescribed voltage waveform as a function of time on the edge ring electrode. The second voltage supply system includes a third voltage supply and a fourth voltage supply. The third voltage supply is configured to generate a second temporally constant voltage magnitude. The fourth voltage supply is configured to generate a second temporally varying voltage. The second temporally constant voltage magnitude and the second temporally varying voltage combine to form the second prescribed voltage waveform.

In an example embodiment, a method is disclosed for supplying bias voltage during plasma processing of a substrate. The method includes generating a prescribed voltage waveform as a function of time on a bias voltage supply node. The method also includes transmitting a first version of the prescribed voltage waveform from the bias voltage supply node to a primary bias electrode disposed below a substrate support surface to control a voltage on a top surface of a substrate present on the substrate support surface. The method also includes transmitting a second version of the prescribed voltage waveform to an edge ring electrode disposed within an edge ring that circumscribes the substrate support surface to control a voltage on a top surface of the edge ring.

Other aspects and advantages of the embodiments disclosed herein will become more apparent from the following detailed description and the accompanying drawings.

### BRIEF DESCRIPTION OF THE DRAWINGS

FIG. 1A shows a vertical cross-section view through a portion of an example substrate plasma processing system, in accordance with some embodiments.

FIG. 1B shows a top view of the substrate disposed on the substrate support structure, with the edge ring surrounding the substrate support structure, referenced as View A-A in FIG. 1A, in accordance with some embodiments.

FIG. 2A shows an example diagram of the edge ring next to the substrate support structure, with the substrate on the substrate support surface, in accordance with some embodiments.

FIG. 2B shows a waveform for RF bias voltage applied to the top surface of the substrate and a waveform for RF bias voltage applied to the top surface of the edge ring, in accordance with some embodiments.

FIG. 3 shows example arbitrary (non-sinusoidal) bias voltage waveforms that may be applied to each of the top surface of the substrate and the top surface of the edge ring by way of the primary bias electrode and the edge ring electrode, respectively, in accordance with some embodiments.

FIG. 4 shows application of the pulsed voltage waveform to both the primary bias electrode and the edge ring electrode to create a flat plasma sheath boundary in the example of FIG. 2A, in accordance with some embodiments.

FIG. 5 shows application of the pulsed voltage waveform of FIG. 4 to the primary bias electrode in conjunction with application of a shorter duty cycle pulsed voltage waveform to the edge ring electrode, in accordance with some embodiments.

FIG. 6 shows the pulsed voltage waveform applied to the top surface of the substrate and the pulsed voltage waveform applied to the top surface of the edge ring, with the pulsed voltage waveform on the edge ring phase-shifted relative to the pulsed voltage waveform on the substrate, in accordance with some embodiments.

FIG. 7 shows application of the pulsed voltage waveform with increasing magnitude slope of FIG. 3 to the primary bias electrode and application of the pulsed voltage waveform with decreasing magnitude slope of FIG. 3 to the edge ring electrode, in accordance with some embodiments.

FIG. 8 shows application of a pulsed voltage waveform to the primary bias electrode in conjunction with application of a pulsed voltage waveform to the edge ring electrode, where the pulsed voltage waveform on the edge ring includes level-to-level pulsing states, in accordance with some embodiments.

FIG. 9A shows an example implementation of the bias voltage supply system of FIG. 1A for implementing the various methods described with regard to FIGS. 3 through 8 in which various bias voltage waveforms are applied to the top surface of the substrate and the top surface of the edge ring to control the plasma sheath boundary profile near the edge of the substrate, in accordance with some embodiments.

FIG. 9B shows an example implementation of the voltage supply system, in accordance with some embodiments.

FIG. 10 shows an example bias voltage pulsed waveform generated by the voltage supply system, and a corresponding bias voltage waveform on the top surface of the substrate, and a corresponding bias voltage waveform on the top surface of the edge ring, in accordance with some embodiments.

FIG. 11A shows a chart of the various ways in which the splitting circuit can be configured in the bias voltage supply system of FIG. 9A, in accordance with various embodiments.

FIG. 11B shows a chart depicting the possible engagement/disengagement settings of the series capacitor, the shunt capacitor, the series capacitor, and the shunt capacitor, as referenced in FIG. 11A, in accordance with some embodiments.

FIG. 12 shows an example RF bias voltage waveform generated in conjunction with the bias voltage pulsed waveform, in accordance with some embodiments.

FIG. 13 shows another bias voltage supply system for implementing the various methods described with regard to FIGS. 3 through 8 in which various bias voltage waveforms are applied to the top surface of the substrate and the top surface of the edge ring to control the plasma sheath boundary profile near the edge of the substrate, in accordance with some embodiments.

FIG. 14 shows an example diagram of the controller, in accordance with some embodiments.

FIG. 15 shows a flowchart of a method for supplying bias voltage during plasma processing of a substrate, in accordance with some embodiments.

### DETAILED DESCRIPTION

In the following description, numerous specific details are set forth in order to provide a thorough understanding of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

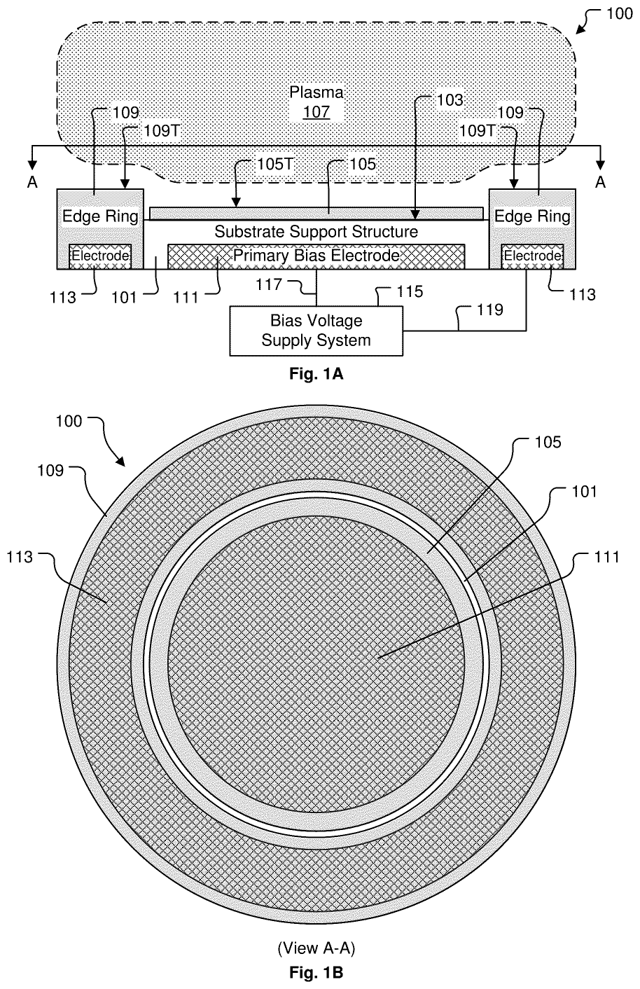

FIG. 1A shows a vertical cross-section view through a portion of an example substrate plasma processing system 100, in accordance with some embodiments. The system 100 includes a substrate support structure 101 that has a substrate support surface 103 configured to support a substrate 105 during processing of the substrate 105 by a plasma 107 generated above the substrate support structure 101. In some embodiments, the substrate support structure 101 is an electrostatic chuck configured to generate an electrostatic force that holds the substrate 105 to the substrate support surface 103. In some embodiments, an edge ring 109 surrounds the substrate support structure 101, such that the substrate support surface 103 is circumscribed by the edge ring 109.

FIG. 1B shows a top view of the substrate 105 disposed on the substrate support structure 101, with the edge ring 109 surrounding the substrate support structure 101, referenced as View A-A in FIG. 1A, in accordance with some embodiments. In some embodiments, RF power is transmitted from a coil, an electrode, and/or an antenna into a plasma processing region overlying the substrate support structure 101 into which a process gas (or gas mixture) is supplied. The RF power transforms the process gas/mixture into the plasma 107 within the plasma processing region. The plasma 107 is generated to cause a change to the substrate 105 in a controlled manner. In various fabrication processes, the change to the substrate 105 can be a change in material or surface condition on the substrate 105. For example, in various fabrication processes, the change to the substrate 105 can include one or more of etching of a material from the substrate 105, deposition of a material on the substrate 105, and/or modification of material present on the substrate 105. It should be understood that the plasma processing system 100 can be any type of plasma processing system in which RF power is transmitted to the process gas/mixture within the plasma processing region to generate the plasma 107 over the substrate 105 supported on the substrate support structure 101.

In some embodiments, the substrate 105 is a semiconductor wafer undergoing a fabrication procedure. However, it should be understood that in various embodiments, the substrate 105 can be essentially any type of substrate that is subjected to a plasma-based fabrication process. For example, in some embodiments, the substrate 105 is formed of silicon, sapphire, GaN, GaAs or SiC, and/or other substrate materials, and can include glass panels/substrates, metal foils, metal sheets, polymer materials, or the like. Also, in various embodiments, the substrate 105 may vary in form, shape, and/or size. For example, in some embodiments, the substrate 105 is a semiconductor wafer with an outer diameter of 200 mm, 300 mm, 450 mm, or another size. Also, in some embodiments, the substrate 105 is a non-circular substrate, such as a rectangular substrate for a flat panel display, or the like, among other shapes.

A primary bias electrode 111 is disposed within the substrate support structure 101 below the substrate support surface 103. In some embodiments, the substrate support structure 101 is formed of a dielectric material, such as a ceramic material or other type of dielectric material, with the primary bias electrode 111 formed of an electrically conductive material. An edge ring electrode 113 is disposed within the edge ring 109. In some embodiments, the edge ring 109 is formed of a dielectric material, with the edge ring electrode 113 formed of an electrically conductive material. The primary bias electrode 111 is electrically connected to a bias voltage supply system 115, as indicated by connection 117. The edge ring electrode 113 is also electrically connected to the bias voltage supply system 115, as indicated by connection 119. The bias voltage supply system 115 is configured to control a voltage on the primary bias electrode 111 and a voltage on the edge ring electrode 113. The primary bias electrode 111 is configured to control a voltage on a top surface 105T of the substrate 105 when the substrate 105 is present on the substrate support surface 103. The voltage applied to the primary bias electrode 111 may be different than the corresponding voltage on the top surface 105T of the substrate 105 due to various materials present between the primary bias electrode 111 and the top surface 105T of the substrate 105, such as the combination of the dielectric material of the substrate support structure 101 above the primary bias electrode 111 and the material(s) of the substrate 105 itself. In some embodiments, the material(s) present between the primary bias electrode 111 and the top surface 105T of the substrate 105 can be electrically represented as a substantially fixed capacitance. The edge ring electrode 113 is configured to control a voltage on a top surface 109T of the edge ring 109. The voltage applied to the edge ring electrode 113 may be different than the corresponding voltage on the top surface 109T of the edge ring 109 due to the material of the edge ring 109 above the edge ring electrode 113. In some embodiments, the material(s) of the edge ring 109 above the edge ring electrode 113 can be electrically represented as a substantially fixed capacitance.

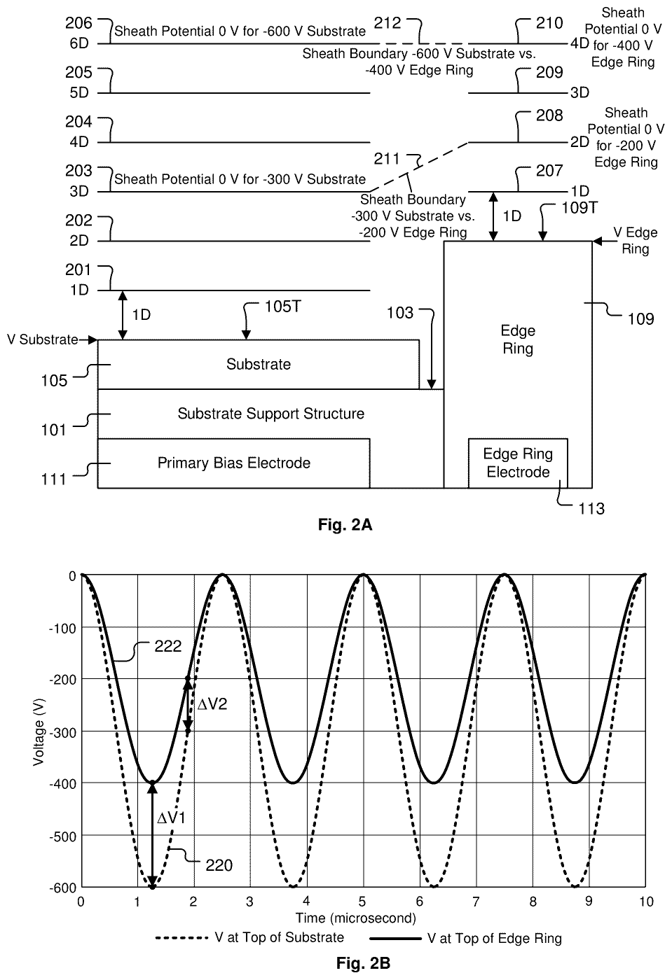

FIG. 2A shows a close-up vertical cross-section view of the edge ring 109 next to the substrate support structure 101, with the substrate 105 on the substrate support surface 103, in accordance with some embodiments. In this example, the top surface 109T of the edge ring 109 is higher than the top surface 105T of the substrate 105. Vertical heights 1D, 2D, 3D, 4D, 5D, and 6D above the top surface 105T of the substrate 105 are depicted by lines 201, 202, 203, 204, 205, and 206, respectively. Successive ones of the vertical heights 1D, 2D, 3D, 4D, 5D, and 6D are separated by a constant distance increment of 1D, where D is an arbitrary distance. Vertical heights 1D, 2D, 3D, and 4D above the top surface 109T of the edge ring 109 are depicted by lines 207, 208, 209, and 210, respectively. Successive ones of the vertical heights 1D, 2D, 3D, and 4D above the edge ring 109 are separated by the constant distance increment of 1D.

A plasma sheath thickness above the substrate 105 is the distance from the top surface 105T of the substrate 105 to the bulk of the plasma 107. Similarly, a plasma sheath thickness above the edge ring 109 is the distance from the top surface 109T of the edge ring 109 to the bulk of the plasma 107. Application of negative voltage on the top surface 105T of the substrate 105, by way of the primary bias electrode 111 establishes the plasma sheath above the substrate 105. The voltage on the top surface 105T of the substrate 105 controls the thickness of the plasma sheath above the substrate 105. Application of negative voltage on the top surface 109T of the edge ring 109, by way of the edge ring electrode 113 establishes the plasma sheath above the edge ring 109. The voltage on the top surface 109T of the edge ring 109 controls the thickness of the plasma sheath above the edge ring 109. The thickness of the plasma sheath above the substrate 105 is dependent in-part on the voltage on the top surface 105T of the substrate 105. Similarly, the thickness of the plasma sheath above the edge ring 109 is dependent in-part on the voltage on the top surface 109T of the edge ring 109. In the example of FIG. 2A, a voltage potential of −100 V on the top surface 105T of the substrate 105 moves the plasma sheath boundary the distance increment of 1D away from the top surface 105T of the substrate 105. Similarly, in the example of FIG. 2A, a voltage potential of −100 V on the top surface 109T of the edge ring 109 moves the plasma sheath boundary the distance increment of 1D away from the top surface 109T of the edge ring 109.

As bombarding ions from the plasma 107 travel through the plasma sheath, the ions gain kinetic energy toward the direction that is perpendicular to the equipotential lines that define the plasma sheath. Also, the ion angular distribution function (IADF) is minimized (close to zero degree) when the equipotential lines that the define the plasma sheath are flat throughout the path of the traveling ions. Ideally, the plasma sheath boundary is flat across the substrate 105 and the edge ring 109, such that the IADF is perpendicular (90 degrees) to the top surface 105T of the substrate 105 all the way to the outer peripheral edge of the substrate 105. For example, in FIG. 2A, when the voltage on the top surface 105T of the substrate 105 is −600 V and the voltage on the top surface 109T of the edge ring 109 is −400 V, the plasma sheath boundary over the transition between the substrate 105 and the edge ring 109 is flat, as indicated by lines 206, 212, and 210, such that ions within the plasma sheath will not gain substantial horizontal energy, i.e., the ions will travel toward the substrate 105 in a direction substantially perpendicular to the top surface 105T of the substrate 105.

FIG. 2B shows a waveform 220 for RF bias voltage applied to the top surface 105T of the substrate 105 and a waveform 222 for RF bias voltage applied to the top surface 109T of the edge ring 109, in accordance with some embodiments. The waveforms 220 and 222 have the same frequency and are synchronized in phase. The waveform 220 has the peak negative voltage of −600 V, and the waveform 222 has the peak negative voltage of −400 V, corresponding to a potential difference (ΔV1) of −200 V. Therefore, when the waveforms 220 and 222 are at the their respective peak negative voltages, the plasma sheath boundary is flat across the transition between the substrate 105 and the edge ring 109, as indicated by lines 206, 212, and 210 in FIG. 2A. However, at other phases of the waveforms 220 and 222, the voltage on the top surface 105T of the substrate 105 and the top surface 109T of the edge ring 109 do not provide for a flat plasma sheath boundary across the transition between the substrate 105 and the edge ring 109. For example, when the voltage on the top surface 105T of the substrate 105 is −300 V, the voltage on the top surface 109T of the edge ring 109 is −200V, corresponding to a potential difference (ΔV2) of −100 V, which does not provide for a flat plasma sheath boundary across the transition between the substrate 105 and the edge ring 109, as indicated by lines 203, 211, and 208 in FIG. 2A. As the RF bias voltage waveforms 220 and 222 cycle in phase, the plasma sheath boundary bends up and down at the transition between the top surface 105T of the substrate 105 and the top surface 109T of the edge ring 109. This bending of the plasma sheath boundary causes the bombarding ions (such as used for reactive ion etching) to be incident on the substrate 105 at an angle that is not perpendicular to the top surface 105T of the substrate 105. The increase in IADF of the bombarding ions at the edge of the substrate 105 causes non-uniformity in process results (e.g., etch rate, etch profile, etc.) at the edge of the substrate 105, which usually requires empirical evaluation, such as by imaging of the substrate 105 etch profile results for different applied sinusoidal RF bias voltage waveforms.

When sinusoidal RF bias voltage is used to bias the substrate 105, discontinuity of the substrate 105, the primary bias electrode 111, and the edge ring 109 structures near the edge of the substrate 105 often causes non-uniform process results on the substrate 105. Also, the example of FIGS. 2A and 2B shows that sinusoidal waveforms are incapable of providing an ideal flat plasma sheath boundary across the transition between the substrate 105 and the edge ring 109 over the time period for bombarding ions traveling through the plasma sheath unless the top surface 105T of the substrate 105 and the top surface 109T of the edge ring 109 are at the same elevation (at the same horizontal plane).

In some embodiments, independent RF bias is added under the edge ring 109 in order to control the uniformity of process results on the substrate 105 near the outer peripheral edge of the substrate 105. However, RF biasing of the substrate 105 and edge ring 109 has a relatively broad ion energy distribution (IED) and lacks the control of ion energy level and the full-width-at-half-maximum (FWHM) of the IED above the substrate 105 and/or the edge ring 109. Additionally, edge ring 109 erosion by reactive ion etching is another issue associated with supplying sinusoidal RF bias voltage to the edge ring electrode 113. Edge ring 109 erosion can add operation cost in manufacturing due to more frequent replacement of the edge ring 109, which can reduce the benefit in manufacturing yield that is provided by use of the edge ring 109.

Narrow IED provides advantages to achieve desired plasma process results on the substrate 105 as compared with wide IED in various applications, such as reactive ion etching (RIE), atomic layer deposition (ALD), atomic layer etching (ALE), among others. Narrow IED can be obtained with constant negative voltage on the surface 105T of the substrate 105 being processed, such as on a silicon wafer for plasma etching and/or deposition. Also, there are many substrates 105 and substrate support structures 101 made of dielectric material. Unless the primary bias electrode 111 voltage is controlled, positively charged ions will travel through the plasma sheath so as to reduce the negative surface charge on the top surface 105T of the substrate 105 and correspondingly reduce the sheath potential. In some embodiments, a linear slope of the primary bias electrode 111 voltage is used to keep a constant negative voltage on the top surface 105T of the substrate 105, with the assumption of substantially constant ion flux through the plasma sheath. However, in some embodiments, when the ion flux through the plasma is time-varying, a non-linear slope of the primary bias electrode 111 voltage is used to keep a constant negative voltage on the top surface 105T of the substrate 105.

In some situations, excessive magnitude of voltage would be required on the primary bias electrode 111, if the plasma sheath maintains without collapse even for a relatively short period of time (>1 millisecond) as compared to the processing time (>>1 second). Implementation of a high voltage generator to supply the excessive magnitude of voltage on the primary bias electrode 111 is costly and inefficient. Also, charge buildup is another issue associated with the relatively long period of time over which negative voltage is present on the top surface 105T of the substrate 105. Periodically switching polarity of the voltage on the primary bias electrode 111 resolves these issues concerning excessive magnitude of voltage requirements and charge buildup. In order to obtain a narrow IED, it is necessary to avoid a collisional sheath, which occurs if the sheath travel time of ion (t_ion) is greater than the duration of the constant negative voltage (t_Vneg) on the top surface 105T of the substrate 105. Fast switching frequency leads to such a condition (t_ion>t_Vneg) due to short t_Vneg. Therefore, a linear slope of the voltage on the order of microseconds could be necessary on the primary bias electrode 111. In some embodiments, the switching frequency is between 10 kiloHertz to 1 megaHertz.

There are two parameters to control in the non-sinusoidal voltage source: Vstep and dV/dT. In some embodiments, the voltage applied to the primary bias electrode 111 stays substantially steady over a period of time in order to discharge the substrate 105 that is charged by positive ions. The plasma sheath collapses during this period of time. Then, Vstep is applied to the primary bias electrode 111 to achieve a target negative voltage on the top surface 105T of the substrate 105. Then, after the target negative voltage is achieved on the top surface 105T of the substrate 105 by Vstep, the voltage slope dV/dT is applied to the primary bias electrode 111 until the end of the switching cycle so as to maintain the target negative voltage on the top surface 105T of the substrate 105. The voltage Vstep sets the desired ion energy, and the voltage dV/dT sets the full-width-at-half-maximum (FWHM) of the IED. The voltage dV/dT=I_ion/C_substrate, where I_ion is the ion current incident upon the substrate 105 and C_substrate is the capacitance between the top surface 105T of the substrate 105 and the primary bias electrode 111 to which the controlled bias voltage is directly or indirectly applied. The above-mentioned process of applying Vstep and dV/dT to achieve and maintain the target negative voltage on the top surface 105T of the substrate 105 by way of the primary bias electrode 111 can also be used to achieve and maintain a target voltage on the top surface 109T of the edge ring 109 by way of the edge ring electrode 113.

Uniform IED over the substrate surface is important for manufacturing yield. However, IED is often non-uniform near the edge of the substrate because of the discontinuity of the substrate, the base plate electrode, and the edge ring structures. In accordance with various embodiments disclosed herein, independent non-sinusoidal voltage control over the edge ring 109 provides a control of IED uniformity over the edge of the substrate 105. An independent voltage source is used to provide the independent non-sinusoidal voltage control over the edge ring 109. The independent voltage source is aligned with the voltage switching on the primary bias electrode 111 in a way to provide substantially uniform process results throughout the substrate 105.

In some embodiments, the edge ring electrode 113 is used to provide for the independent IED control over the top surface 109T of the edge ring 109. Insertion of the edge ring electrode 113 below the top surface 109T of the edge ring 109 can be achieved in various ways. In an example embodiment, the edge ring electrode 113 is electrically separated from the primary bias electrode 111. In this embodiment, an independent voltage source is implemented for the edge ring electrode 113. In another example embodiment, the edge ring electrode 113 is branched from the primary bias electrode 111. In some embodiments, the edge ring electrode 113 is an additional electrode that is branched from the primary bias electrode 111. In some embodiments, the edge ring electrode 113 is formed as an expansion of the primary bias electrode 111. The embodiments in which the edge ring electrode 113 is branched from the primary bias electrode 111 do not require an independent voltage source for the edge ring electrode 113. Rather, in the embodiments in which the edge ring electrode 113 is branched from the primary bias electrode 111, the voltage on the edge ring electrode 113 is controlled with an edge ring 109 capacitance optimization to substantially match the substrate 105 capacitance. In various embodiments, various techniques such as variable capacitor and temperature-controlled capacitance are used for edge ring 109 capacitance optimization. The various embodiments disclosed herein for applying independent non-sinusoidal voltage and IED control over the edge ring 109 provide for improved process uniformity near the edge of the substrate 105. The various embodiments disclosed herein also provide a new tool for improving the process uniformity in terms of IED controlled by non-sinusoidal voltage source and edge ring 109 capacitance.

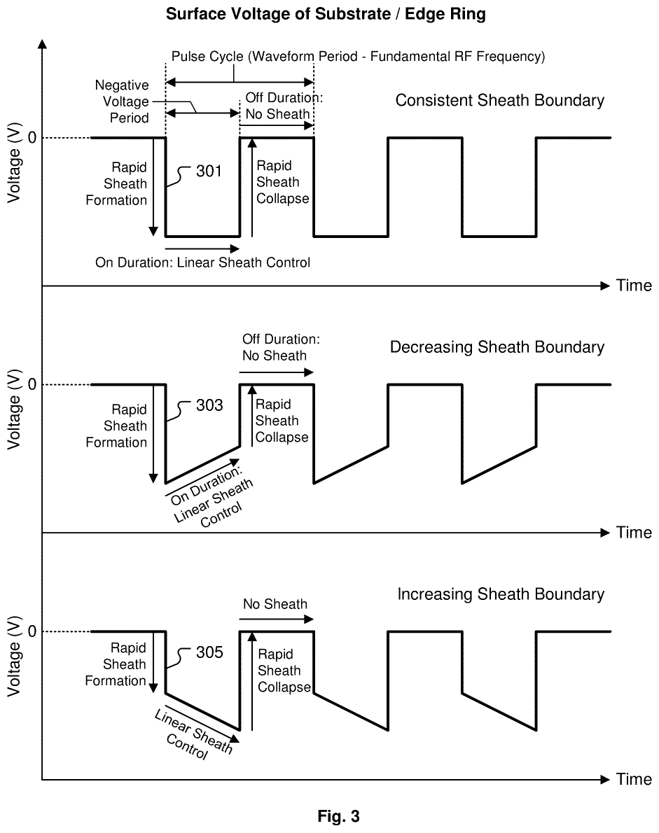

In some embodiments, separate arbitrary (non-sinusoidal) bias voltage waveforms are applied to each of the substrate 105 and edge ring 109, respectively, in order to maintain a substantially flat plasma sheath boundary across the transition between the substrate 105 and the edge ring 109. FIG. 3 shows example arbitrary (non-sinusoidal) bias voltage waveforms that may be applied to each of the top surface 105T of the substrate 105 and the top surface 109T of the edge ring 109 by way of the primary bias electrode 111 and the edge ring electrode 113, respectively, in accordance with some embodiments. It should be understood that the bias voltage waveforms of FIG. 3 are shown by way of example. In other embodiments, essentially any arbitrary (non-sinusoidal) bias voltage waveform may be applied to the top surface 105T of the substrate 105 and the top surface 109T of the edge ring 109 as needed to achieve and maintain the substantially flat plasma sheath boundary across the transition between the substrate 105 and the edge ring 109. FIG. 3 shows a pulsed voltage waveform 301 defined as an ongoing series of pulse cycles, where each pulse cycle corresponds to a waveform period and includes an on-duration in which the pulsed voltage waveform 301 has a negative voltage and an off-duration in which the pulsed voltage waveform 301 has a positive voltage. At the beginning of the pulse cycle in the waveform 301, rapid sheath formation occurs in response to a step change (increase) in the bias voltage magnitude. Over the on-duration of the pulse cycle in the waveform 301, the negative bias voltage is maintained substantially constant so as to maintain a consistent plasma sheath boundary thickness. Over the off-duration of the pulse cycle in the waveform 301, rapid plasma sheath collapse occurs in response to a step change from the negative bias voltage to a positive voltage on the top surface 105T of the substrate 105 or top surface 109T of the edge ring 109.

FIG. 3 also shows a pulsed voltage waveform 303 defined as an ongoing series of pulse cycles, where each pulse cycle corresponds to a waveform period and includes an on-duration in which the pulsed voltage waveform 303 has a negative voltage and an off-duration in which the pulsed voltage waveform 303 has a positive voltage. At the beginning of the pulse cycle in the waveform 303, rapid sheath formation occurs in response to a step change (increase) in the bias voltage magnitude. Over the on-duration of the pulse cycle in the waveform 303, the bias voltage magnitude is linearly decreased as a function of time so as to achieve a decreasing plasma sheath boundary thickness as a function of time. Over the off-duration of the pulse cycle in the waveform 303, rapid plasma sheath collapse occurs in response to a step change from the negative bias voltage to a positive voltage on the top surface 105T of the substrate 105 or top surface 109T of the edge ring 109.

FIG. 3 also shows a pulsed voltage waveform 305 defined as an ongoing series of pulse cycles, where each pulse cycle corresponds to a waveform period and includes an on-duration in which the pulsed voltage waveform 305 has a negative voltage and an off-duration in which the pulsed voltage waveform 305 has a positive voltage. At the beginning of the pulse cycle in the waveform 305, rapid sheath formation occurs in response to a step change (increase) in the bias voltage magnitude. Over the on-duration of the pulse cycle in the waveform 305, the bias voltage magnitude is linearly increased as a function of time so as to achieve an increasing plasma sheath boundary thickness as a function of time. Over the off-duration of the pulse cycle in the waveform 305, rapid plasma sheath collapse occurs in response to a step change from the negative bias voltage to a positive voltage on the top surface 105T of the substrate 105 or top surface 109T of the edge ring 109.

In FIG. 3, the waveform period (pulse cycle) represents the total time that establishes and removes the plasma sheath. In some embodiments, the negative voltage magnitude during the on-duration of the pulse cycle is set to induce ion bombardment for reactive ion etching. The duty cycle of the waveforms 301, 303, 305 is controlled by adjusting the percentage of the waveform period (pulse cycle) that corresponds to the on-duration. The example waveforms 301, 303, and 305 can be applied to both the primary bias electrode 111 and the edge ring electrode 113.

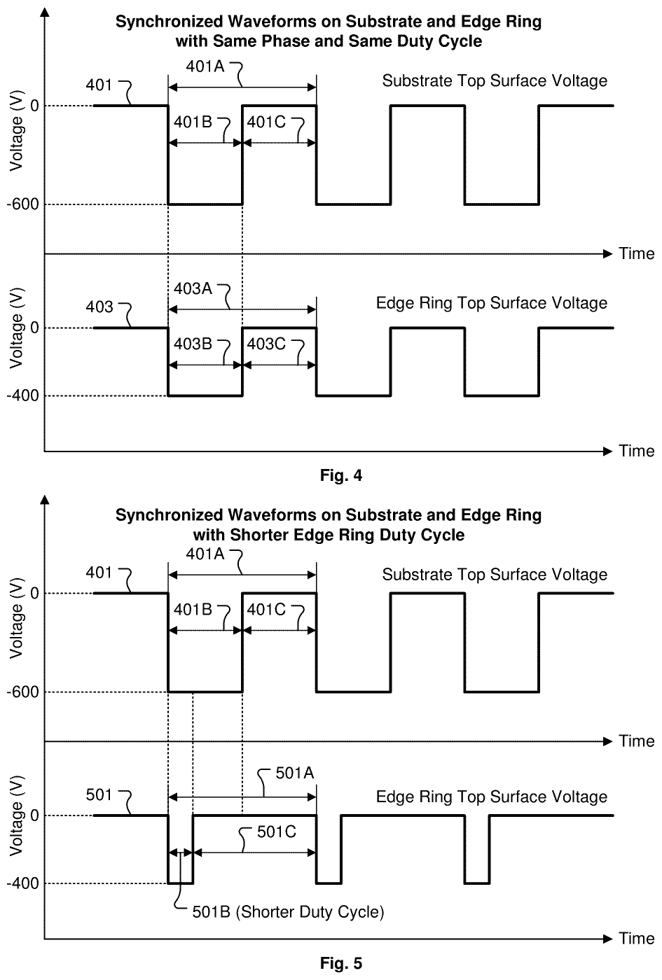

FIG. 4 shows application of the pulsed voltage waveform 301 to both the primary bias electrode 111 and the edge ring electrode 113 to create a flat plasma sheath boundary in the example of FIG. 2A, in accordance with some embodiments. Specifically, a pulsed voltage waveform 401 represents the voltage on the top surface 105T of the substrate 105 corresponding to application of the pulsed voltage waveform 301 to the primary bias electrode 111. A pulsed voltage waveform 403 represents the voltage on the top surface 109T of the edge ring 109 corresponding to application of the pulsed voltage waveform 301 to the edge ring electrode 113. The waveform 401 has a pulse cycle 401A that includes an on-duration 401B and an off-duration 401C. The waveform 403 has a pulse cycle 403A that includes an on-duration 403B and an off-duration 403C. The pulsed voltage waveforms 401 and 403 are synchronized with regard to phase and duty cycle. The on-duration 401B of the pulse cycle 401A applies a bias voltage of −600 V to the top surface 105T of the substrate 105 by way of the primary bias electrode 111. Simultaneously, the on-duration 403B of the pulse cycle 403A applies a bias voltage of −400 V to the top surface 109T of the edge ring 109 by way of the edge ring electrode 113. Therefore, in the example of FIG. 2A, the plasma sheath boundary is flat across the transition between the substrate 105 and edge ring 109, as indicated by lines 206, 212, and 210, over the on-durations 401B and 403B of the pulse cycles 401A and 403A, respectively, of the pulsed voltage waveforms 401 and 403, respectively. Also, the plasma sheath collapses during the off-durations 401C and 403C of the pulse cycles 401A and 403A, respectively, of the pulsed voltage waveforms 401 and 403, respectively. In the example of FIG. 2A, the pulsed voltage waveforms 401 and 403 create a flat plasma sheath boundary during the negative bias voltage period which is much longer than the ion travel time through the plasma sheath. Also, the substrate 105 and edge ring 109 bias voltages are aligned with identical phase and duty cycle so that the shape of the plasma sheath boundary is steady during the negative bias voltage period and so that the bombarding IADF can be minimized (close to zero degree).

FIG. 5 shows application of the pulsed voltage waveform 401 of FIG. 4 to the primary bias electrode 111 in conjunction with application of a shorter duty cycle pulsed voltage waveform 501 to the edge ring electrode 113, in accordance with some embodiments. The pulsed voltage waveform 501 has a pulse cycle 501A that includes an on-duration 501B and an off-duration 501C. The pulsed voltage waveform 503 has a shorter duty cycle in comparison with the pulsed voltage waveform 401 because the percentage of the pulse cycle 501A corresponding to on-duration 501B is less than the percentage of the pulse cycle 401A corresponding to the on-duration 401B. With the magnitude of the voltage on the top surface 109T of the edge ring 109 set to flatten the plasma sheath boundary above the edge of the substrate 105, the angle of travel of the bombarding ions is around zero degree relative to the normal vector extending from the top surface 105T of the substrate 105 during the on-duration 501B of the pulse cycle 501A of the pulsed voltage waveform 501 applied to the top surface 109T of the edge ring 109. The on-durations 401B and 501B can be set to longer and shorter than the ion travel time through the plasma sheath, respectively. Under such condition, during the off-duration 501C of the pulse cycle 501A of the pulsed voltage waveform 501, most of the bombarding ions will be in the middle of the plasma sheath where ions are predominantly affected by the voltage on the top surface 105T of the substrate 105 because voltage gradients become smaller closer to the top surface 105T of the substrate 105. Therefore, the ions that were initially moving perpendicularly above the top surface 109T of the edge ring 109 will lose their energy during the off-duration 501C of the pulse cycle 501A of the pulsed voltage waveform 501 and gain relatively small kinetic energy toward the substrate 105. Correspondingly, the shorter duty cycle of the pulsed voltage waveform 501 applied to the top surface 109T of the edge ring 109 will serve to reduce erosion of the edge ring 109 during reactive ion etching processes.

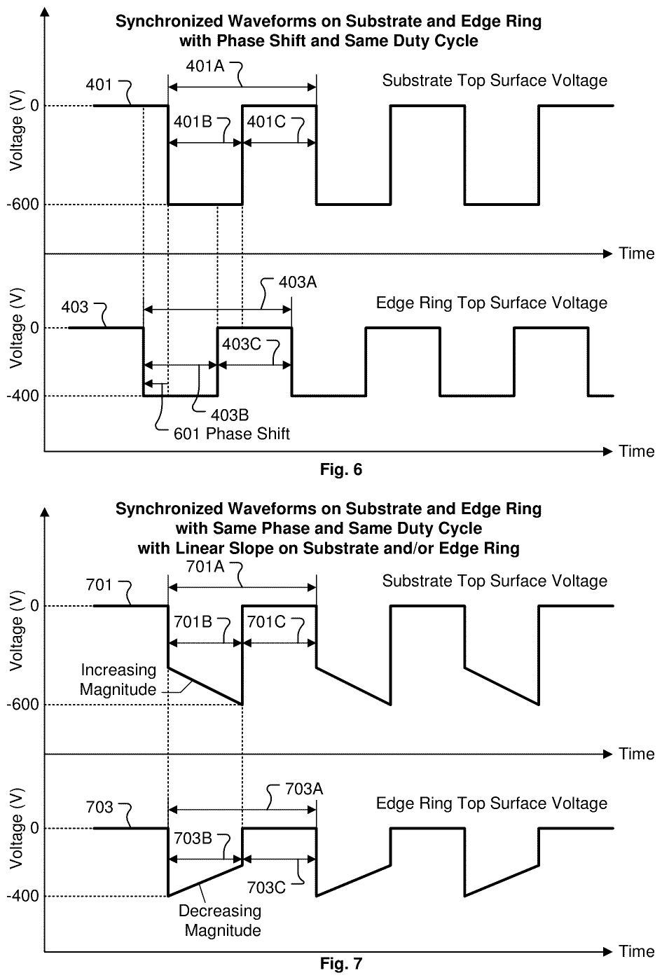

FIG. 6 shows the pulsed voltage waveform 401 applied to the top surface 105T of the substrate 105 and the pulsed voltage waveform 403 applied to the top surface 109T of the edge ring 109, with the pulsed voltage waveform 403 phase-shifted relative to the pulsed voltage waveform 401, in accordance with some embodiments. Specifically, the pulsed voltage waveform 403 is phase-shifted by a phase shift amount 601, such that the pulse cycle 403A of the pulsed voltage waveform 403 starts before the pulse cycle 401A of the pulsed voltage waveform 401. In some embodiments, the phase shift amount 601 is set so that the etch rate of the edge of the substrate 105 is reduced by attracting the bombarding ions initially toward the edge ring 109 during the phase shift amount 601 before the start of the on-duration 401B (negative voltage) of the pulse cycle 401A of the pulsed voltage waveform 401 on the top surface 105T of the substrate 105. In this manner, the phase shift amount 601 serves to reduce the number of bombarding ions incident on the edge of the substrate 105 by moving ions that are initially above the edge of the substrate 105 toward the edge ring 109. Also, in some embodiments, the phase shift amount 601 causes ions to initially travel toward the edge ring 109 when the phase cycle 403A of the pulsed voltage waveform 403 begins, and then turn perpendicular to the substrate 105 when the phase cycle 401A of the pulsed voltage waveform 401 begins. In some embodiments, the phase-shifted pulsed voltage waveform 403 of FIG. 6 reduces the etch rate at the outer peripheral edge of the substrate 105 when the ion density near the edge of the substrate 105 is larger due to structural, temporal, and/or electrical discontinuities around the periphery of the substrate 105. Also, it should be understood that in some embodiments, the pulsed voltage waveform 403 is phase shifted in the other direction, such that the pulse cycle 403A of the pulsed voltage waveform 403 starts some phase shift amount after the pulse cycle 401A of the pulsed voltage waveform 401 starts.

FIG. 7 shows application of the pulsed voltage waveform 305 of FIG. 3 to the primary bias electrode 111 and application of the pulsed voltage waveform 303 of FIG. 3 to the edge ring electrode 113, in accordance with some embodiments. Specifically, a pulsed voltage waveform 701 represents the voltage on the top surface 105T of the substrate 105 corresponding to application of the pulsed voltage waveform 305 to the primary bias electrode 111. A pulsed voltage waveform 703 represents the voltage on the top surface 109T of the edge ring 109 corresponding to application of the pulsed voltage waveform 303 to the edge ring electrode 113. The waveform 701 has a pulse cycle 701A that includes an on-duration 701B and an off-duration 701C. The waveform 703 has a pulse cycle 703A that includes an on-duration 703B and an off-duration 703C. The pulsed voltage waveforms 701 and 703 are synchronized with regard to phase and duty cycle. The on-duration 701B of the pulse cycle 701A applies a bias voltage to the top surface 105T of the substrate 105 that increases linearly in magnitude as a function of time from an initial step voltage magnitude to a voltage of −600 V. Simultaneously, the on-duration 703B of the pulse cycle 703A applies a bias voltage to the top surface 109T of the edge ring 109 that decreases linearly in magnitude as a function of time from an initial step voltage of −400 V.

In some embodiments, the voltage slope of the pulsed voltage waveform 701 during the on-duration 701B and the voltage slope of the pulsed voltage waveform 703 during the on-duration 703B are collectively adjusted to improve the plasma process results by manipulating the ion movement near the edge of the substrate 105. The particular example of FIG. 7 serves to reduce the etch rate at the edge of the substrate 105 without changing the duty cycle or the phase alignment between pulsed voltage waveform 701 on the top surface 105T of the substrate 105 and the pulsed voltage waveform 703 on the top surface 109T of the edge ring 109. In some embodiments, a bend in the plasma sheath boundary between the substrate 105 and the edge ring 109 inverts during the on-durations 701B and 703B of the pulse cycles 701A and 703A, respectively, of the pulsed voltage waveforms 701 and 703, respectively. It should be understood, however, that in various embodiments, the pulsed voltage waveforms 701 and 703 can be configured to change as a function of time in essentially any manner required during the on-durations 701B and 703B, respectively, of the pulse cycles 701A and 703A, respectively.

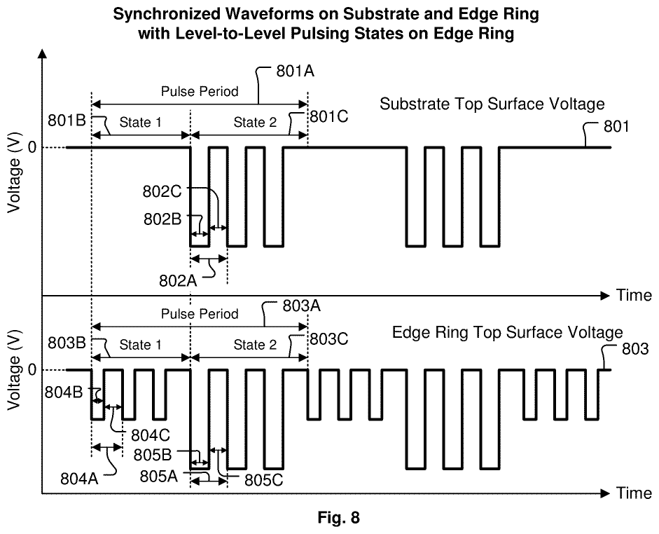

FIG. 8 shows application of a pulsed voltage waveform 801 to the primary bias electrode 111 in conjunction with application of a pulsed voltage waveform 803 to the edge ring electrode 113, where the pulsed voltage waveform 803 includes level-to-level pulsing states, in accordance with some embodiments. The pulsed voltage waveform 801 includes a successive series of pulse cycles 801A. The pulsed voltage waveform 803 includes a successive series of pulse cycles 803A. The pulsed voltage waveforms 801 and 803 are synchronized with regard to phase. In other words, the same pulse cycle 803A of the pulsed voltage waveform 803 occurs over the temporal course of each pulse cycle 801A of the pulsed voltage waveform 801. The pulsed voltage waveform 801 represents the voltage on the top surface 105T of the substrate 105 corresponding to application of a similar pulsed voltage waveform to the primary bias electrode 111. The pulsed voltage waveform 803 represents the voltage on the top surface 109T of the edge ring 109 corresponding to application of a similar pulsed voltage waveform to the edge ring electrode 113.

The waveform 801 has a pulse cycle 801A that includes a first state 801B in which the voltage on the top surface 105T of the substrate 105 is zero or positive. The pulse cycle 801A of the waveform 801 also has a second state 801C in which the voltage on the top surface 105T of the substrate 105 is sub-pulsed in accordance with a series of sub-pulse cycles 802A, where each sub-pulse cycle 802A includes an on-duration 802B and an off-duration 802C. The percentage of the sub-pulse cycle 802A having the on-duration 802B defines the duty cycle of the sub-pulse cycle 802A, where this duty cycle can be adjusted as needed to achieve desired effects on the charged constituents above the substrate 105.

The waveform 803 has a pulse cycle 803A that includes a first state 803B and a second state 803C. In the first state 803B, the voltage on the top surface 109T of the edge ring 109 is sub-pulsed in accordance with a series of sub-pulse cycles 804A, where each sub-pulse cycle 804A includes an on-duration 804B and an off-duration 804C. The percentage of the sub-pulse cycle 804A having the on-duration 804B defines the duty cycle of the sub-pulse cycle 804A. Similarly, in the second state 803C, the voltage on the top surface 109T of the edge ring 109 is sub-pulsed in accordance with a series of sub-pulse cycles 805A, where each sub-pulse cycle 805A includes an on-duration 805B and an off-duration 805C. The percentage of the sub-pulse cycle 805A having the on-duration 805B defines the duty cycle of the sub-pulse cycle 805A. The duty cycles of the sub-pulse cycles 804A and 805A can be adjusted as needed to achieve desired effects on the charged constituents above/near the edge of the substrate 105 and above the edge ring 109.

In the example embodiment of FIG. 8, the magnitude of the bias voltage applied to the top surface 109T of the edge ring 109 is lower in the first state 803B than in the second state 803C, which is referred to as level-to-level bias voltage pulsing on the edge ring 109. It should be understood that in various embodiments, level-to-level bias voltage pulsing can be applied to the edge ring 109, the substrate 105, or both the edge ring 109 and the substrate 105. Also, in various embodiments, the bias voltage magnitudes applied in the level-to-level bias voltage pulsing can be controlled as needed. Also, in various embodiments, the duty cycles applied in the level-to-level bias voltage pulsing can be controlled as needed. Also, in various embodiments, the time lengths of the different states 801B and 801C within the pulse cycle 801A can be defined as needed. And, the time lengths of the different states 803B and 803C within the pulse cycle 803A can be defined as needed. Additionally, while the example of FIG. 8 shows the pulse cycle 801A as having the two states 801B and 801C, and the pulse cycle 803A as having the two states 803B and 803C, it should be understood that in various embodiments either or both of the pulse cycles 801A and 803A can be defined to include more than two states, where each state is characterized by a particular combination of bias voltage magnitude, sub-pulse duty cycle, sub-pulse temporal length, and state temporal length.

The particular example of level-to-level bias voltage pulsing shown in FIG. 8 serves to reduce the ion density above the edge of the substrate 105 during the combined application of the first state 801B of pulse cycle 801A to the top surface 105T of the substrate 105 and the first state 803B of the pulse cycle 803A to the top surface 109T of the edge ring 109. Also, the level-to-level bias voltage pulsing example of FIG. 8 serves to minimize the IADF above the edge of the substrate 105 during the combined application of the second state 801C of pulse cycle 801A to the top surface 105T of the substrate 105 and the second state 803C of the pulse cycle 803A to the top surface 109T of the edge ring 109. In this manner, the level-to-level bias voltage pulsing example of FIG. 8 serves to move ions toward the edge ring 109 and away from the edge of the substrate 105, which can serve to reduce plasma density near the edge of the substrate 105 in order to provide for etch control at the edge of the substrate 105, e.g., in order to reduce etch rate at the edge of the substrate 105. In some embodiments, such as shown in FIG. 8, level-to-level bias voltage pulsing includes both pulsed voltage waveform synchronization and pulsing state synchronization on the top surface 105T of the substrate 105 relative to the top surface 109T of the edge ring 109.

As discussed with regard to the examples of FIGS. 3 through 8, various bias voltage waveforms can be applied to the top surface 105T of the substrate 105 and the top surface 109T of the edge ring 109 to control the plasma sheath boundary profile near the edge of the substrate 105. Ions travel across the plasma sheath above the substrate 105 in accordance with the plasma sheath potential created by the voltage present on the top surface 105T of the substrate 105. When the voltage on the substrate 105 oscillates between positive and negative, the plasma sheath potential reflects the voltage oscillation on the substrate 105, and ions traveling through the plasma sheath are correspondingly affected by the varying plasma sheath potential. At relatively low RF frequency, the travel time of bombarding ions within the plasma sheath (plasma sheath thickness/average ion velocity) can be shorter than the period of a single RF bias voltage waveform. The variation in plasma sheath potential corresponding to the RF bias voltage frequency instantaneously affects the movement of ions traveling within the plasma sheath. The various embodiments disclosed herein for applying controlled arbitrary (non-sinusoidal) pulsed bias voltage waveforms to the top surface 105T of the substrate 105 and the top surface 109T of the edge ring 109 enable control of the ions traveling within the plasma sheath at certain location(s) in the plasma sheath and at certain time(s) within each pulsed bias voltage waveform period in order to improve etch uniformity near the edge of the substrate 105. The various embodiments disclosed herein for applying controlled arbitrary (non-sinusoidal) pulsed bias voltage waveforms to the top surface 105T of the substrate 105 and the top surface 109T of the edge ring 109 are significantly advantageous over various existing technologies that seek to control the average movement of ions regardless of time and location of the ions within the plasma sheath. Additionally, the various embodiments disclosed herein for applying controlled arbitrary (non-sinusoidal) pulsed bias voltage waveforms to the top surface 105T of the substrate 105 and the top surface 109T of the edge ring 109 provide for improvement in the process uniformity results across the substrate 105, while mitigating associated issues with having a powered edge ring 109 in various plasma etching applications.

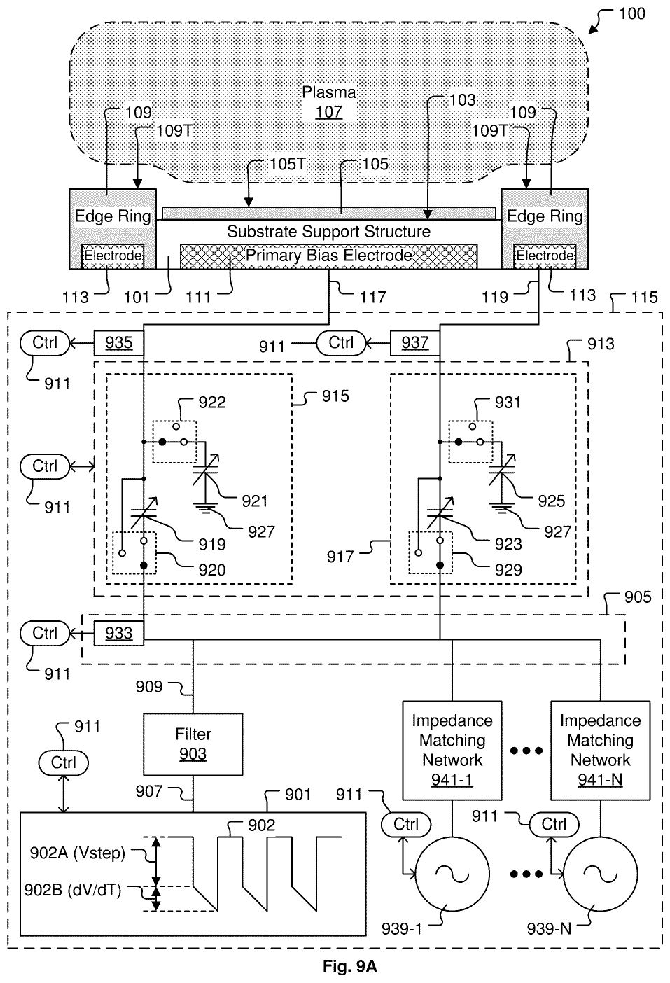

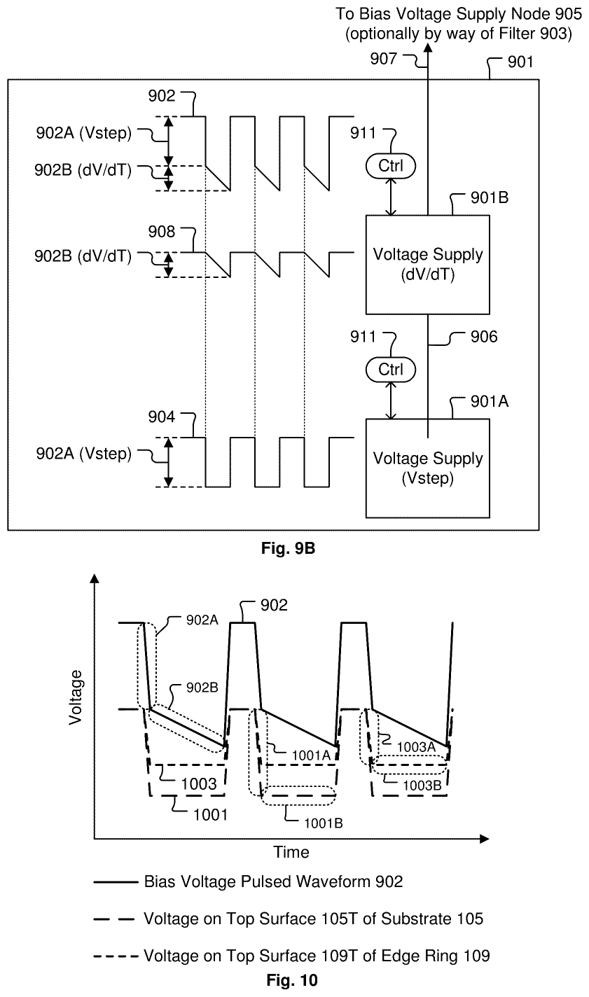

FIG. 9A shows an example implementation of the bias voltage supply system 115 of FIG. 1A for implementing the various methods described with regard to FIGS. 3 through 8 in which various bias voltage waveforms are applied to the top surface 105T of the substrate 105 and the top surface 109T of the edge ring 109 to control the plasma sheath boundary profile near the outer peripheral edge of the substrate 105, in accordance with some embodiments. The primary bias electrode 111 and the edge ring electrode 113, along with their associated electrical connections 117 and 119, respectively, can be considered as components of the bias voltage supply system 115. The bias voltage supply system 115 includes a voltage supply system 901 having an output electrically connected through a filter 903 to a bias voltage supply node 905, as indicated by connections 907 and 909. The voltage supply system 901 is configured to generate a prescribed voltage waveform 902 as a function of time on the bias voltage supply node 905. In some embodiments, the prescribed voltage waveform 902 includes a bias voltage step portion (Vstep) 902A and a temporally varying bias voltage portion (dV/dT) 902B. In some embodiments, the prescribed voltage waveform 902 is defined as an ongoing series of pulse cycles, where each pulse cycle includes an on-duration and an off-duration, such as previously described with regard to the pulsed voltage waveforms of FIGS. 3 through 8. The voltage supply system 901 is connected in bidirectional data/signal communication with a controller 911 that is programmable to direct operation of the voltage supply system 901 to generate essentially any form of prescribed voltage waveform 902 as required for a particular plasma processing operation on the substrate 105.

FIG. 9B shows an example implementation of the voltage supply system 901, in accordance with some embodiments. The voltage supply system 901 includes a first voltage supply 901A and a second voltage supply 901B, electrically connected in series with each other, such that their output voltages combine in sum. In some embodiments, each of the first voltage supply 901A and the second voltage supply 901B is a direct current voltage supply. The first voltage supply 901A is configured to generate a temporally constant voltage magnitude in accordance with a prescribed pulse schedule corresponding to the prescribed voltage waveform 902. For example, FIG. 9B shows an example pulsed voltage waveform 904 generated and output by the first voltage supply 901A, which will eventually become the bias voltage step portion (Vstep) 902A of the prescribed voltage waveform 902. An output of the first voltage supply 901A is electrically connected to an input of the second voltage supply 901B, as indicated by electrical connection 906. An output of the second voltage supply 901B is electrically connected to the output of the voltage supply system 901, as indicated by the electrical connection 907. The second voltage supply 901B is configured to generate a temporally varying pulsed voltage waveform 908, which will eventually become the temporally varying bias voltage portion (dV/dT) 902B of the prescribed voltage waveform 902. In some embodiments, the temporally varying pulsed voltage waveform 908 varies substantially linearly as a function of time during the on-duration of each pulse cycle. Also, in some embodiments, the temporally varying pulsed voltage waveform 908 increases in magnitude in a substantially linear manner as a function of time during the on-duration of each pulse cycle. At the output of the second voltage supply 901B, the pulsed voltage waveform 904 is combined with the temporally varying pulsed voltage waveform 908 to generate the prescribed voltage waveform 902. In this manner, the output voltage provided by the voltage supply system 901 to the bias voltage supply node 905 is the combination of the pulsed voltage waveform 904 generated by the first voltage supply 901A and the pulsed voltage waveform 908 generated by the second voltage supply 901B. Each of the first voltage supply 901A and the second voltage supply 901B is connected in bidirectional data/signal communication with the controller 911, with the controller 911 directing operation of the first voltage supply 901A and the second voltage supply 901B to synchronize the phases and the duty cycles of the pulsed voltage waveforms 904 and 908 in order to generate the prescribed voltage waveform 902.

The bias voltage supply system 115 includes a splitting circuit 913 configured to apply voltage present on the bias voltage supply node 905 to each of the primary bias electrode 111 and the edge ring electrode 113 in a controlled manner. The splitting circuit 913 includes a first branch circuit 915 and a second branch circuit 917. The first branch circuit 915 is electrically connected between the bias voltage supply node 905 and the primary bias electrode 111. The first branch circuit 915 includes a series capacitor 919 and a shunt capacitor 921. In some embodiments, each of the series capacitor 919 and the shunt capacitor 921 is a respective variable capacitor that can have its capacitance setting controlled remotely by way of the controller 911 that is in bidirectional data/signal communication with the splitting circuit 913. In some embodiments, the first branch circuit 915 includes a switching device 920 implemented to enable bypassing of the series capacitor 919, such that the bias voltage supply node 905 can be switchably electrically connected to either an input terminal of the series capacitor 919 or directly to the primary bias electrode 111 by way of the electrical connection 117. In this manner, the switching device 920 is controlled to either make the series capacitor 919 be serially electrically connected between the bias voltage supply node 905 and the primary bias electrode 111, or effectively electrically remove the series capacitor 919 from being disposed between the bias voltage supply node 905 and the primary bias electrode 111. Also, in some embodiments, the first branch circuit 915 includes a switching device 922 implemented so that the shunt capacitor 921 can be electrically connected to or disconnected from the electrical connection 117 that extends from the output of the first branch circuit 915 to the primary bias electrode 111. In this manner, the switching device 922 is controlled to either electrically connect the shunt capacitor 921 between the primary bias electrode 111 and a reference ground potential 927, or effectively electrically remove the shunt capacitor 921 from the first branch circuit 915.

The second branch circuit 917 is electrically connected between the bias voltage supply node 905 and the edge ring electrode 113. The second branch circuit 917 includes a series capacitor 923 and a shunt capacitor 925. In some embodiments, each of the series capacitor 923 and the shunt capacitor 925 is a respective variable capacitor that can have its capacitance setting controlled remotely by way of the controller 911 that is in bidirectional data/signal communication with the splitting circuit 913. In some embodiments, the second branch circuit 917 includes a switching device 929 implemented to enable bypassing of the series capacitor 923, such that the bias voltage supply node 905 can be switchably electrically connected to either an input terminal of the series capacitor 923 or directly to the edge ring electrode 113 by way of the electrical connection 119. In this manner, the switching device 929 is controlled to either make the series capacitor 923 be serially electrically connected between the bias voltage supply node 905 and the edge ring electrode 113, or effectively electrically remove the series capacitor 923 from being disposed between the bias voltage supply node 905 and the edge ring electrode 113. Also, in some embodiments, the second branch circuit 917 includes a switching device 931 implemented so that the shunt capacitor 925 can be electrically connected to or disconnected from the electrical connection 119 that extends from the output of the second branch circuit 917 to the edge ring electrode 113. In this manner, the switching device 931 is controlled to either electrically connect the shunt capacitor 925 between the edge ring electrode 113 and the reference ground potential 927, or effectively electrically remove the shunt capacitor 925 from the second branch circuit 917.

In some embodiments, the first branch circuit 915 is configured so that the series capacitor 919 and the shunt capacitor 921 are disengaged, and the second branch circuit 917 is configured so that the series capacitor 923 and the shunt capacitor 925 are engaged. More specifically, in these embodiments, the switching devices 920 and 922 are set so that the bias voltage supply node 905 is directly electrically connected to the primary bias electrode 111, and the switching devices 929 and 931 are set so that the bias voltage conveyed from the bias voltage supply node 905 to the edge ring electrode 113 is controlled by the series capacitor 923 and the shunt capacitor 925. Thus, in these embodiments, the bias voltage pulsed waveform 902 output by the voltage supply system 901 is supplied to the primary bias electrode 111, and a modified version of the bias voltage pulsed waveform 902 output by the voltage supply system 901 is supplied to the edge ring electrode 113.

In some embodiments, the first branch circuit 915 is configured so that the series capacitor 919 and the shunt capacitor 921 are engaged, and the second branch circuit 917 is configured so that the series capacitor 923 and the shunt capacitor 925 are engaged. More specifically, in these embodiments, the switching devices 920 and 922 are set so that the bias voltage conveyed from the bias voltage supply node 905 to the primary bias electrode 111 is controlled by the series capacitor 919 and the shunt capacitor 921, and the switching devices 929 and 931 are set so that the bias voltage conveyed from the bias voltage supply node 905 to the edge ring electrode 113 is controlled by the series capacitor 923 and the shunt capacitor 925. Thus, in these embodiments, a first modified version of the bias voltage pulsed waveform 902 output by the voltage supply system 901 is supplied to the primary bias electrode 111, and a second modified version of the bias voltage pulsed waveform 902 output by the voltage supply system 901 is supplied to the edge ring electrode 113.

Additionally, in some embodiments, the series capacitor 919 can be engaged in the first branch circuit 915, with the shunt capacitor 921 disengaged. In some embodiments, the shunt capacitor 921 can be engaged in the first branch circuit 915, with the series capacitor 919 disengaged. Also, in some embodiments, the series capacitor 923 can be engaged in the second branch circuit 917, with the shunt capacitor 925 disengaged. In some embodiments, the shunt capacitor 925 can be engaged in the second branch circuit 917, with the series capacitor 923 disengaged.

In some embodiments a voltage sensor 933, e.g., voltage/current sensor (VI sensor), is connected to measure the real-time voltage on the bias voltage supply node 905, and convey this measured voltage to the controller 911. In some embodiments a voltage sensor 935, e.g., voltage/current sensor (VI sensor), is connected to measure the real-time voltage at the output of the first branch circuit 915, and convey this measured voltage to the controller 911. In some embodiments a voltage sensor 937, e.g., voltage/current sensor (VI sensor), is connected to measure the real-time voltage at the output of the second branch circuit 917, and convey this measured voltage to the controller 911. In various embodiments, the controller 911 is configured to use the voltages measured by one or more of the voltage sensors 933, 935, and 937 as feedback signal(s) for controlling operation of the voltage supply system 901 and one or more of the series capacitor 919, the shunt capacitor 921, the series capacitor 923, and the shunt capacitor 925.

Also, in some embodiments, the bias voltage supply system 115 includes a number (N) of RF generators 939-1 to 939-N, where N is greater than or equal to 1, connected to supply RF bias voltage to the bias voltage supply node 905 by way of a respective impedance matching network 941-1 to 941-N. Each of the RF generators 939-1 to 939-N is connected in bidirectional data/signal communication with the controller 911. At the bias voltage supply node 905, the RF voltage signal(s) output by the RF generators 939-1 to 939-N combine with the bias voltage pulsed waveform 902 output by the voltage supply system 901. The RF generators 939-1 to 939-N and corresponding impedance matching networks 941-1 to 941-N are implemented in some embodiments of the bias voltage supply system 115. However, in other embodiments of the bias voltage supply system 115, the RF generators 939-1 to 939-N and corresponding impedance matching networks 941-1 to 941-N are not implemented.

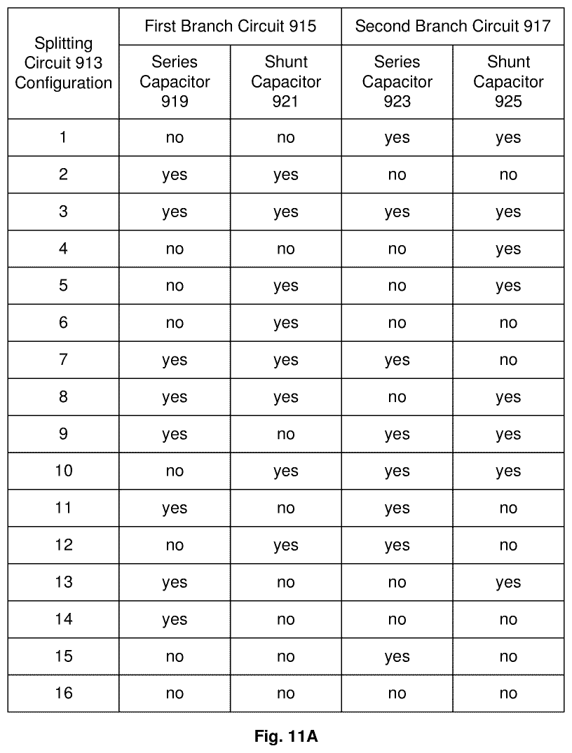

FIG. 10 shows an example bias voltage pulsed waveform 902 generated by the voltage supply system 901, and a corresponding bias voltage waveform 1001 on the top surface 105T of the substrate 105, and a corresponding bias voltage waveform 1003 on the top surface 109T of the edge ring 109, in accordance with some embodiments. The bias voltage pulsed waveform 902 includes the bias voltage step portion (Vstep) 902A and the temporally varying bias voltage portion (dV/dT) 902B. The bias voltage waveform 902 is generated on the bias voltage supply node 905. Therefore, the bias voltage waveform 1001 on the top surface 105T of the substrate 105 is based on the bias voltage waveform 902 as modified by the first branch circuit 915. Similarly, the bias voltage waveform 1003 on the top surface 109T of the edge ring 109 is based on the bias voltage waveform 902 as modified by the second branch circuit 917. The bias voltage waveform 1001 includes a step portion 1001A and a slope portion 1001B. The bias voltage waveform 1003 includes a step portion 1003A and a slope portion 1003B.

The shunt capacitor 921 in the first branch circuit 915 controls the magnitude of the step portion 1001A of the bias voltage waveform 1001 on the top surface 105T of the substrate 105. Specifically, the capacitance setting of the shunt capacitor 921 can be controlled to set the magnitude of the step portion 1001A at a percentage (0 to 100%) of the magnitude of the bias voltage step portion (Vstep) 902A. If the shunt capacitor 921 is disengaged (or not present) in the first branch circuit 915, the magnitude of the step portion 1001A is a fixed percentage of the magnitude of the bias voltage step portion (Vstep) 902A, depending on the intrinsic capacitive effect of the materials of the substrate support structure 101 and substrate 105 present between the primary bias electrode 111 and the top surface 105T of the substrate 105. The above-mentioned fixed percentage of the magnitude of the bias voltage step portion (Vstep) 902A is dependent on the structure between the output of the voltage supply system 901 and the top surface 105T of the substrate 105. For example, there may be stray shunt capacitances in structures such as the filter 903, the impedance matching networks 941-1 to 941-N, and the electrical connections 907, 909, 905, and 117. Also, when the rising time of the bias voltage step portion (Vstep) 902A is relatively long compared to the ion travel time through the plasma sheath, series capacitances between the output of the voltage supply system 901 and the top surface 105T of the substrate 105 can reduce the above-mentioned fixed percentage of the magnitude of Vstep 902A due to the ion flux during the rising time of Vstep 902A. For example, in some embodiments, various series capacitances may be inserted for some purpose in the filter 903, the substrate support structure 101, the substrate 105, and/or the electrical connections 907, 909, 905, and 117. The reduction in the above-mentioned fixed percentage of the magnitude of Vstep 902A due to series capacitances can be mostly eliminated by having a relatively short rising time of Vstep 902A, e.g., Vstep<<1 microsecond.

The series capacitor 919 in the first branch circuit 915 controls the slope (change in voltage with respect to time) of the slope portion 1001B of the bias voltage waveform 1001 on the top surface 105T of the substrate 105. When voltage is applied to the primary bias electrode 111 there is an ion current toward the top surface 105T of the substrate 105 from the plasma 107, which discharges the negative charges on the top surface 105T of the substrate 105 and correspondingly causes a decrease in the magnitude of the negative voltage on the top surface 105T of the substrate 105 over time. In order to compensate for this ion-induced decrease in magnitude of the negative voltage on the top surface 105T of the substrate 105, the temporally varying bias voltage portion (dV/dT) 902B of the bias voltage pulsed waveform 902 provides an increase in bias voltage over time. The capacitance setting of the series capacitor 919 is controlled to tune the change in bias voltage as a function of time on the top surface 105T of the substrate 105 to compensate for the ion-induced discharge of the negative charges on the top surface 105T of the substrate 105. In some embodiments, the capacitance setting of the series capacitor 919 is controlled to maintain a substantially constant voltage on the top surface 105T of the substrate 105 during the on-duration of the bias voltage pulsed waveform 902. However, in other embodiments, the capacitance setting of the series capacitor 919 is controlled to achieve a desired change in voltage as a function of time (positive dV/dT and/or negative dV/dT) on the top surface 105T of the substrate 105 during the on-duration of the bias voltage pulsed waveform 902. If the series capacitor 919 is disengaged/bypassed (or not present) in the first branch circuit 915, the change in voltage as a function of time (dV/dT) on the top surface 105T of the substrate 105 during the on-duration of the bias voltage pulsed waveform 902 will follow the temporally varying bias voltage portion (dV/dT) 902B of the bias voltage pulsed waveform 902, with a fixed voltage magnitude offset based on the intrinsic capacitive effect of the materials of the substrate support structure 101 and substrate 105 present between the primary bias electrode 111 and the top surface 105T of the substrate 105. In some embodiments, the above-mentioned fixed voltage magnitude offset can also be based on the intrinsic series capacitances between the output of the voltage supply system 901 and the top surface 105T of the substrate 105. In some embodiments, the above-mentioned intrinsic series capacitances correspond to various series capacitances inserted for some purpose in the filter 903, the substrate support structure 101, the substrate 105, and/or the electrical connections 907, 909, 905, and 117.

The shunt capacitor 925 in the second branch circuit 917 controls the magnitude of the step portion 1003A of the bias voltage waveform 1003 on the top surface 109T of the edge ring 109. Specifically, the capacitance setting of the shunt capacitor 925 can be controlled to set the magnitude of the step portion 1003A at a percentage (0 to 100%) of the magnitude of the bias voltage step portion (Vstep) 902A. If the shunt capacitor 925 is disengaged (or not present) in the second branch circuit 917, the magnitude of the step portion 1003A is a fixed percentage of the magnitude of the bias voltage step portion (Vstep) 902A, depending on the intrinsic capacitive effect of the edge ring 109 material present between the edge ring electrode 113 and the top surface 109T of the edge ring 109. In some embodiments, the magnitude of the step portion 1003A can also be based on the intrinsic series capacitances between the output of the voltage supply system 901 and the top surface 109T of the edge ring 109. In some embodiments, the above-mentioned intrinsic series capacitances correspond to various series capacitances inserted for some purpose in the filter 903, the edge ring 109, and/or the electrical connections 907, 909, 905, and 119.

The series capacitor 923 in the second branch circuit 917 controls the slope (change in voltage with respect to time) of the slope portion 1003B of the bias voltage waveform 1003 on the top surface 109T of the edge ring 109. When voltage is applied to the edge ring electrode 113 there is an ion current toward the top surface 109T of the edge ring 109 from the plasma 107, which discharges the negative charges on the top surface 109T of the edge ring 109 and correspondingly causes a decrease in the magnitude of the negative voltage on the top surface 109T of the edge ring 109 over time. In order to compensate for this ion-induced decrease in magnitude of the negative voltage on the top surface 109T of the edge ring 109, the temporally varying bias voltage portion (dV/dT) 902B of the bias voltage pulsed waveform 902 provides an increase in bias voltage over time. The capacitance setting of the series capacitor 923 is controlled to tune the change in bias voltage as a function of time on the top surface 109T of the edge ring 109 to compensate for the ion-induced discharge of the negative charges on the top surface 109T of the edge ring 109. In some embodiments, the capacitance setting of the series capacitor 923 is controlled to maintain a substantially constant voltage on the top surface 109T of the edge ring 109 during the on-duration of the bias voltage pulsed waveform 902. However, in other embodiments, the capacitance setting of the series capacitor 923 is controlled to achieve a desired change in voltage as a function of time (positive dV/dT and/or negative dV/dT) on the top surface 109T of the edge ring 109 during the on-duration of the bias voltage pulsed waveform 902. If the series capacitor 923 is disengaged/bypassed (or not present) in the second branch circuit 917, the change in voltage as a function of time (dV/dT) on the top surface 109T of the edge ring 109 during the on-duration of the bias voltage pulsed waveform 902 will follow the temporally varying bias voltage portion (dV/dT) 902B of the bias voltage pulsed waveform 902, with a fixed voltage magnitude offset based on the intrinsic capacitive effect of the edge ring 109 material present between the edge ring electrode 113 and the top surface 109T of the edge ring 109. In some embodiments, the above-mentioned fixed voltage magnitude offset can also be based on the intrinsic series capacitances between the output of the voltage supply system 901 and the top surface 109T of the edge ring 109. In some embodiments, the above-mentioned intrinsic series capacitances correspond to various series capacitances inserted for some purpose in the filter 903, the edge ring 109, and/or the electrical connections 907, 909, 905, and 119.

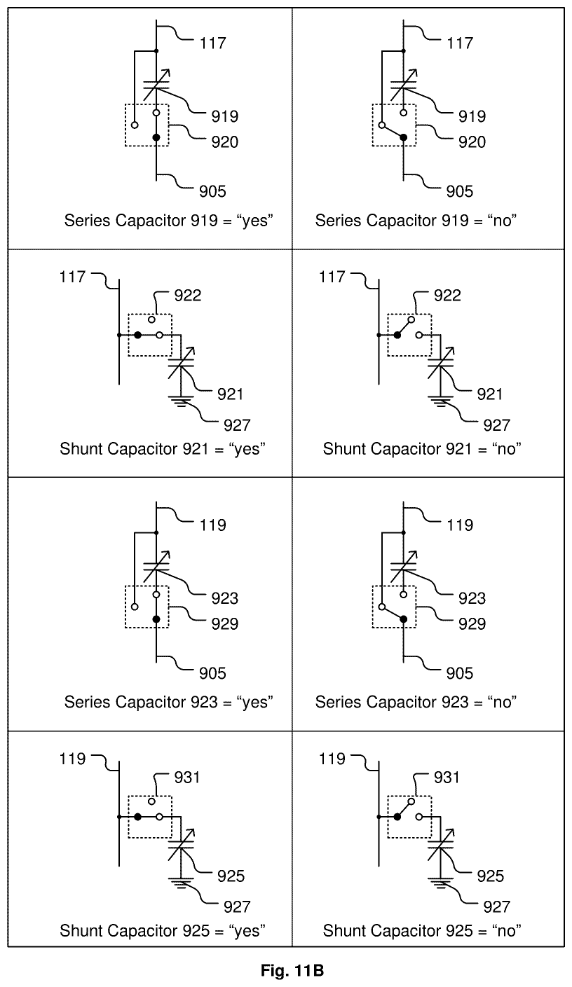

FIG. 11A shows a chart of the various ways in which the splitting circuit 913 can be configured, in accordance with various embodiments. A given configuration of the splitting circuit 913 corresponds to a particular engagement/disengagement combination of the series capacitor 919, the shunt capacitor 921, the series capacitor 923, and the shunt capacitor 925. FIG. 11B shows a chart depicting the possible engagement/disengagement settings of the series capacitor 919, the shunt capacitor 921, the series capacitor 923, and the shunt capacitor 925, in accordance with some embodiments. The engagement designation “yes” and disengagement designation “no” as referenced in FIG. 11B for each of the series capacitor 919, the shunt capacitor 921, the series capacitor 923, and the shunt capacitor 925 are used in the chart of FIG. 11A to describe the various possible configurations of the splitting circuit 913.

When the series capacitor 919 is engaged (series capacitor 919=“yes”), the input terminal of the series capacitor 919 is electrically connected to the bias voltage supply node 905, and the output terminal of the series capacitor 919 is electrically connected to the primary bias electrode 111 by way of the electrical connection 117. When the series capacitor 919 is disengaged (series capacitor 919=“no”), the series capacitor 919 is either electrically bypassed or not present in the first branch circuit 915, such that the bias voltage supply node 905 is directly electrically connected to the primary bias electrode 111 by way of the electrical connection 117. When the shunt capacitor 921 is engaged (shunt capacitor 921=“yes”), the input terminal of the shunt capacitor 921 is electrically connected to the primary bias electrode 111 by way of the electrical connection 117, and the output terminal of the shunt capacitor 921 is electrically connected to the reference ground potential 927. When the shunt capacitor 921 is disengaged (shunt capacitor 921=“no”), the shunt capacitor 921 is either electrically disconnected from the primary bias electrode 111 or is not present in the first branch circuit 915.

When the series capacitor 923 is engaged (series capacitor 923=“yes”), the input terminal of the series capacitor 923 is electrically connected to the bias voltage supply node 905, and the output terminal of the series capacitor 923 is electrically connected to the edge ring electrode 113 by way of the electrical connection 119. When the series capacitor 923 is disengaged (series capacitor 923=“no”), the series capacitor 923 is either electrically bypassed or not present in the second branch circuit 917, such that the bias voltage supply node 905 is directly electrically connected to the edge ring electrode 113 by way of the electrical connection 119. When the shunt capacitor 925 is engaged (shunt capacitor 925=“yes”), the input terminal of the shunt capacitor 925 is electrically connected to the edge ring electrode 113 by way of the electrical connection 119, and the output terminal of the shunt capacitor 925 is electrically connected to the reference ground potential 927. When the shunt capacitor 925 is disengaged (shunt capacitor 925=“no”), the shunt capacitor 925 is either electrically disconnected from the edge ring electrode 113 or is not present in the second branch circuit 917.

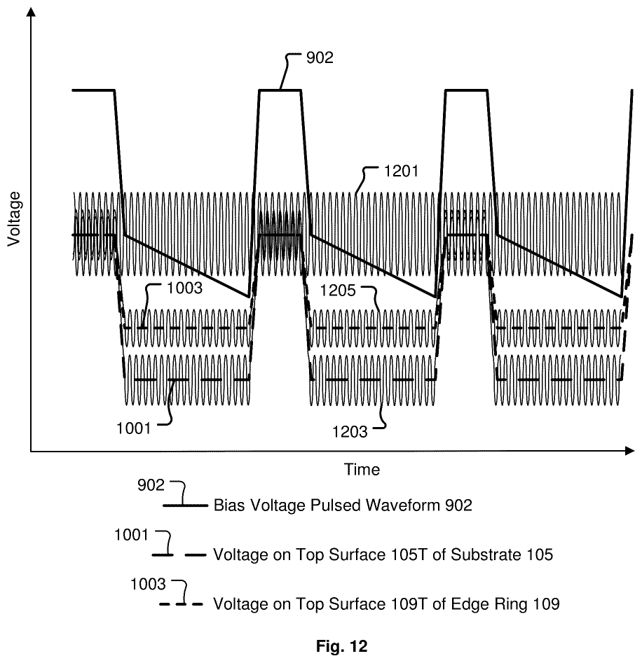

FIG. 12 shows an example RF bias voltage waveform 1201 generated in conjunction with the bias voltage pulsed waveform 902, in accordance with some embodiments. The RF bias voltage waveform 1201 is generated by one or more of the RF generators 939-1 to 939-N and is supplied to the bias voltage supply node 905 in combination with the bias voltage pulsed waveform 902 generated by the voltage supply system 901. The filter 903 is configured to prevent the RF bias voltage waveform 1201 from traveling into the voltage supply system 901. In some embodiments, the filter 903 is a low-pass filter or a notch filter that is configured to block RF frequency signals. In some embodiments, the bias voltage pulsed waveform 902 establishes a baseline voltage waveform that is followed by the RF bias voltage waveform 1201. Because of the splitting circuit 913, a first portion of the RF bias voltage is applied to the primary bias electrode 111 and a second portion of the RF bias voltage is applied to the edge ring electrode 113. The first portion of the RF bias voltage generates an RF bias voltage waveform 1203 on the top surface 105T of the substrate 105. The second portion of the RF bias voltage generates an RF bias voltage waveform 1205 on the top surface 109T of the edge ring 109. The shunt capacitor 921 in the first branch circuit 915 controls a magnitude of the RF bias voltage waveform 1203. Similarly, the shunt capacitor 925 in the second branch circuit 917 controls a magnitude of the RF bias voltage waveform 1205. Therefore, a ratio of the magnitude of the RF bias voltage on the top surface 105T of the substrate 105 to the magnitude of the RF bias voltage on the top surface 109T of the edge ring 109 is proportional to a ratio of the magnitude of the bias voltage waveform 1001 on the top surface 105T of the substrate 105 to the magnitude of the bias voltage waveform 1003 on the top surface 109T of the edge ring 109. As previously mentioned, generation of the RF bias voltage waveform 1201 in conjunction with the bias voltage pulsed waveform 902 is optional.

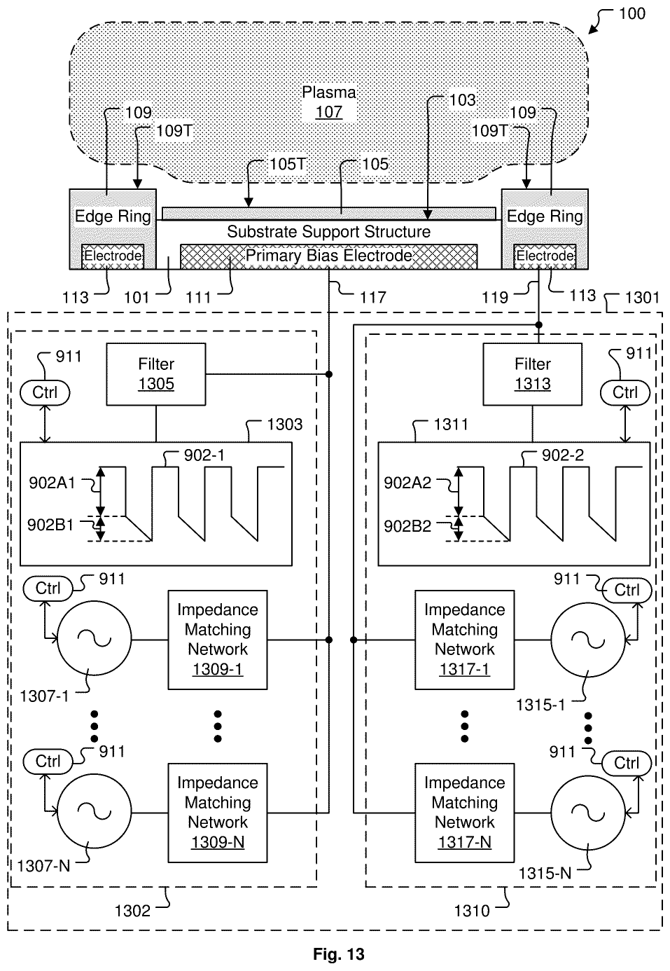

FIG. 13 shows another bias voltage supply system 1301 for implementing the various methods described with regard to FIGS. 3 through 8 in which various bias voltage waveforms are applied to the top surface 105T of the substrate 105 and the top surface 109T of the edge ring 109 to control the plasma sheath boundary profile near the outer peripheral edge of the substrate 105, in accordance with some embodiments. The bias voltage supply system 1301 includes a first voltage supply system 1302 and a second voltage supply system 1310. The first voltage supply system 1302 includes a pulsed voltage generator 1303 having an output connected to the primary bias electrode 111 by way of a filter 1305 and the electrical connection 117. The pulsed voltage generator 1303 is configured in the same way as the voltage supply system 901. Therefore, the pulsed voltage generator 1303 generates and supplies a prescribed voltage waveform 902-1 to the primary bias electrode 111. The prescribed voltage waveform 902-1 includes a step portion 902A1 and a slope portion 902B1. The filter 1305 is configured to prevent RF signals from entering the pulsed voltage generator 1303. In various embodiments, the filter 1305 is a low-pass filter or notch filter.

The first voltage supply system 1302 also optionally includes a number (N) of RF generators 1307-1 to 1307-N, where N is greater than or equal to 1, connected to supply RF bias voltage to the primary bias electrode 111 by way of a respective impedance matching network 1309-1 to 1309-N. Each of the RF generators 1307-1 to 1307-N is connected in bidirectional data/signal communication with the controller 911. The controller 911 operates to synchronize bias voltage waveforms output by the pulsed voltage generator 1303 and each of the RF generators 1307-1 to 1307-N. The RF voltage signal(s) output by the RF generators 1307-1 to 1307-N combine with the bias voltage pulsed waveform 902-1 output by the pulsed voltage generator 1303 on the electrical connection 117. The RF generators 1307-1 to 1307-N and corresponding impedance matching networks 1309-1 to 1309-N are implemented in some embodiments of the first voltage supply system 1302. However, in some embodiments, the RF generators 1307-1 to 1307-N and corresponding impedance matching networks 1309-1 to 1309-N are not implemented in the first voltage supply system 1302.

The second voltage supply system 1310 includes a pulsed voltage generator 1311 having an output connected to the edge ring electrode 113 by way of a filter 1313 and the electrical connection 119. The pulsed voltage generator 1311 is configured in the same way as the voltage supply system 901. Therefore, the pulsed voltage generator 1311 generates and supplies a prescribed voltage waveform 902-2 to the edge ring electrode 113. The prescribed voltage waveform 902-2 includes a step portion 902A2 and a slope portion 902B2. The filter 1313 is configured to prevent RF signals from entering the pulsed voltage generator 1311. In various embodiments, the filter 1313 is a low-pass filter or notch filter.

The second voltage supply system 1310 also optionally includes a number (N) of RF generators 1315-1 to 1315-N, where N is greater than or equal to 1, connected to supply RF bias voltage to the edge ring electrode 113 by way of a respective impedance matching network 1317-1 to 1317-N. Each of the RF generators 1315-1 to 1315-N is connected in bidirectional data/signal communication with the controller 911. The controller 911 operates to synchronize bias voltage waveforms output by the pulsed voltage generator 1311 and each of the RF generators 1315-1 to 1315-N. The RF voltage signal(s) output by the RF generators 1315-1 to 1315-N combine with the bias voltage pulsed waveform 902-2 output by the pulsed voltage generator 1311 on the electrical connection 119. The RF generators 1315-1 to 1315-N and corresponding impedance matching networks 1317-1 to 1317-N are implemented in some embodiments of the second voltage supply system 1310. However, in some embodiments, the RF generators 1315-1 to 1315-N and corresponding impedance matching networks 1317-1 to 1317-N are not implemented in the second voltage supply system 1310.

In some embodiments, the bias voltage pulsed waveform 902-1 is generated to maintain a substantially constant voltage on the top surface 105T of the substrate 105 during the on-duration of each pulse cycle within the bias voltage pulsed waveform 902-1, and the bias voltage pulsed waveform 902-2 is generated to maintain a substantially constant voltage on the top surface 109T of the edge ring 109 during the on-duration of each pulse cycle within the bias voltage pulsed waveform 902-2, such that a substantially constant voltage differential is maintained during the concurrent on-durations of the pulse cycles in the bias voltage pulsed waveforms 902-1 and 902-2, where the substantially constant voltage differential is defined to maintain a substantially flat plasma sheath boundary across the transition between the substrate 105 and the edge ring 109. In some embodiments, the step portion 902A1 of the bias voltage pulsed waveform 902-1 and the step portion 902A2 of the bias voltage pulsed waveform 902-2 are synchronously controlled to achieve a prescribed voltage differential between the top surface 105T of the substrate 105 and the top surface 109T of the edge ring 109. Also, in some embodiments, the slope portion 902B1 of the bias voltage pulsed waveform 902-1 is controlled to compensate for ion-induced discharge of negative charges on the top surface 105T of the substrate 105 over the on-duration of each pulse cycle of the bias voltage pulsed waveform 902-1, such that the voltage on the top surface 105T of the substrate 105 remains substantially constant over the on-duration of each pulse cycle of the bias voltage pulsed waveform 902-1. Also, in some embodiments, the slope portion 902B2 of the bias voltage pulsed waveform 902-2 is controlled to compensate for ion-induced discharge of negative charges on the top surface 109T of the edge ring 109 over the on-duration of each pulse cycle of the bias voltage pulsed waveform 902-2, such that the voltage on the top surface 109T of the edge ring 109 remains substantially constant over the on-duration of each pulse cycle of the bias voltage pulsed waveform 902-2.

The bias voltage pulsed waveforms 902-1 and 902-2 can be respectively generated as needed to the implement the various methods described with regard to FIGS. 3 through 8. In some embodiments, the controller 911 operates to synchronize the phase of the bias voltage pulsed waveforms 902-1 and 902-2. In some embodiments, the controller 911 operates to synchronize both the phase and duty cycle of the bias voltage pulsed waveforms 902-1 and 902-2. In some embodiments, the controller 911 operates to implement a prescribed phase shift between the bias voltage pulsed waveforms 902-1 and 902-2. In some embodiments, the bias voltage pulsed waveforms 902-1 and 902-2 are defined to have a different phase and/or a different duty cycle with respect to each other. Also, in some embodiments, one or both of the bias voltage pulsed waveforms 902-1 and 902-2 is/are defined to implement a prescribed level-to-level pulsing scheme. It should be understood that the bias voltage pulsed waveforms 902-1 and 902-2 are separately and independently controllable with respect to each other.

Additionally, in various embodiments, any number of voltage sensors, e.g., voltage/current sensors (VI sensors), can be connected within the bias voltage supply system 1301 to measure real-time voltage at a particular location, and convey this measured real-time voltage to the controller 911. In some embodiments, the controller 911 is configured to use real-time voltage measurements within the first voltage supply system 1302 and/or the second voltage supply system 1310 to control operation of any one or more of the pulsed voltage generator 1303, the RF generators 1307-1 to 1307-N, the pulsed voltage generator 1311, and the RF generators 1315-1 to 1315-N.

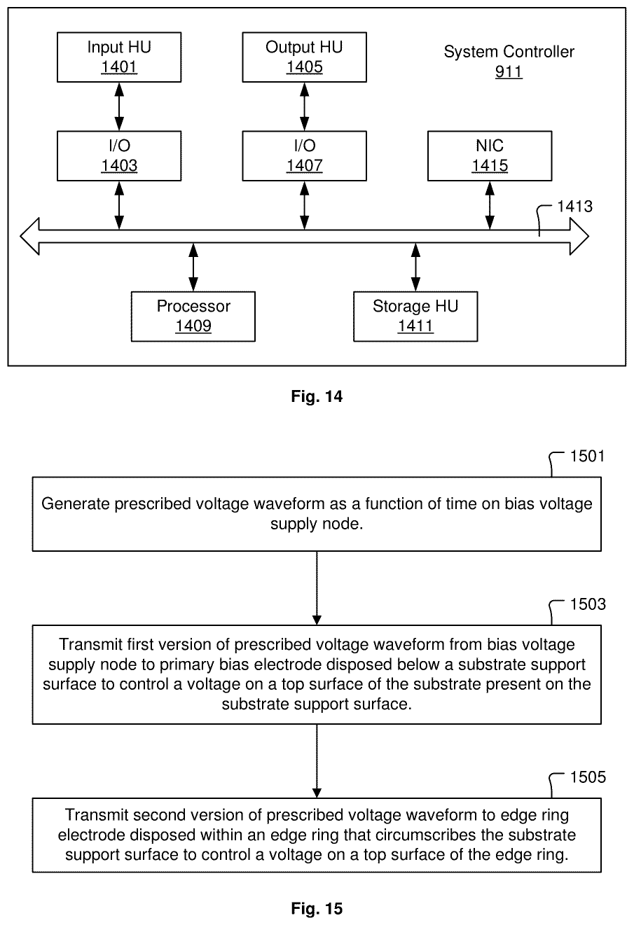

FIG. 14 shows an example diagram of the controller 911, in accordance with some embodiments. In some embodiments, the controller 911 includes a processor 1409, a storage hardware unit (HU) 1411 (e.g., memory), an input HU 1401, an output HU 1405, an input/output (I/O) interface 1403, an I/O interface 1407, a network interface controller (NIC) 1415, and a data communication bus 1413. The processor 1409, the storage HU 1411, the input HU 1401, the output HU 1405, the I/O interface 1403, the I/O interface 1407, and the NIC 1415 are in data communication with each other by way of the data communication bus 1413. Examples of the input HU 1401 include a mouse, a keyboard, a stylus, a data acquisition system, a data acquisition card, etc. Examples of the output HU 1405 include a display, a speaker, a device controller, etc. Examples of the NIC 1415 include a network interface card, a network adapter, etc. In various embodiments, the NIC 1415 is configured to operate in accordance with one or more communication protocols and associated physical layers, such as Ethernet and/or EtherCAT, among others. Each of the I/O interfaces 1403 and 1407 is defined to provide compatibility between different hardware units coupled to the I/O interface. For example, the I/O interface 1403 can be defined to convert a signal received from the input HU 1401 into a form, amplitude, and/or speed compatible with the data communication bus 1413. Also, the I/O interface 1407 can be defined to convert a signal received from the data communication bus 1413 into a form, amplitude, and/or speed compatible with the output HU 1405. Although various operations described herein are performed by the processor 1409 of the controller 911, it should be understood that in some embodiments various operations can be performed by multiple processors of the controller 911 and/or by multiple processors of multiple computing systems connected to the controller 911.

In various embodiments, the substrate plasma processing system 100 is integrated with electronics for controlling its operation before, during, and after processing of the substrate 105, where the electronics are implemented within the controller 911 that is configured and connected to control various components and/or sub-parts of the substrate plasma processing system 100, including the bias voltage supply systems 115 and 1301. Depending on substrate 105 processing requirements and/or the particular configuration of the substrate plasma processing system 100, the controller 911 is programmed to control any process and/or component disclosed herein, including delivery of process gas(es), temperature settings (e.g., heating and/or cooling), pressure settings, vacuum settings, power settings, RF power supply system settings, electrical signal frequency settings, gas flow rate settings, fluid delivery settings, positional and operation settings, bias voltage supply system 115/1301 settings, substrate 105 transfers into and out of the substrate plasma processing system 100 and/or into and out of load locks connected to or interfaced with the substrate plasma processing system 100, among others.

In various embodiments, the controller 911 is defined as electronics having various integrated circuits, logic, memory, and/or software that direct and control various tasks/operations, such as receiving instructions, issuing instructions, controlling device operations, enabling cleaning operations, enabling endpoint measurements, enabling metrology measurements (optical, thermal, electrical, etc.), among other tasks/operations. In some embodiments, the integrated circuits within the controller 911 include one or more of firmware that stores program instructions, a digital signal processor (DSP), an Application Specific Integrated Circuit (ASIC) chip, a programmable logic device (PLD), one or more microprocessors, and/or one or more microcontrollers that execute program instructions (e.g., software), among other computing devices. In some embodiments, the program instructions are communicated to the controller 911 in the form of various individual settings (or program files), defining operational parameters for carrying out a process on the substrate 105 within the substrate plasma processing system 100. In some embodiments, the operational parameters are included in a recipe defined by process engineers to accomplish one or more processing steps during the fabrication of one or more layers, materials, metals, oxides, silicon, silicon dioxide, surfaces, circuits, and/or dies on the substrate 105.

In some embodiments, the controller 911 is a part of, or connected to, a computer that is integrated with, or connected to, the substrate plasma processing system 100, or that is otherwise networked to the substrate plasma processing system 100, or a combination thereof. For example, in some embodiments, the controller 911 is implemented in a “cloud” or all or a part of a fab host computer system, which allows for remote access for control of substrate 105 processing by the substrate plasma processing system 100. The controller 911 enables remote access to the substrate plasma processing system 100 to provide for monitoring of current progress of fabrication operations, provide for examination of a history of past fabrication operations, provide for examination of trends or performance metrics from a plurality of fabrication operations, provide for changing of processing parameters, provide for setting of subsequent processing steps, provide for specification of RF power supply system operational parameters, provide for specification of bias voltage supply system 115/1301 operational parameters, and/or provide for initiation of a new substrate fabrication process.

In some embodiments, a remote computer, such as a server computer system, provides process recipes to the controller 911 over a computer network, which includes a local network and/or the Internet. The remote computer includes a user interface that enables entry or programming of parameters and/or settings, which are then communicated to the controller 911 from the remote computer. In some examples, the controller 911 receives instructions in the form of settings for processing the substrate 105 within the substrate plasma processing system 100. It should be understood that the settings are specific to a type of process to be performed on the substrate 105 and a type of tool/device/component that the controller 911 interfaces with or controls. In some embodiments, the controller 911 is distributed, such as by including one or more discrete controller(s) 911 that are networked together and synchronized to work toward a common purpose, such as operating the substrate plasma processing system 100 to perform a prescribed process on the substrate 105. An example of a distributed controller 911 for such purposes includes one or more integrated circuits on a chamber in communication with one or more integrated circuits located remotely (such as at a platform level or as part of a remote computer) that combine to control a process in the chamber.

FIG. 15 shows a flowchart of a method for supplying bias voltage during plasma processing of the substrate 105, in accordance with some embodiments. The method includes an operation 1501 for generating a prescribed voltage waveform as a function of time on the bias voltage supply node 905. The method also includes an operation 1503 for transmitting a first version of the prescribed voltage waveform from the bias voltage supply node 905 to the primary bias electrode 111 disposed below the substrate support surface 103 to control a voltage on the top surface 105T of the substrate 105 present on the substrate support surface 103. The method also includes an operation 1505 for transmitting a second version of the prescribed voltage waveform to the edge ring electrode 113 disposed within the edge ring 109 that circumscribes the substrate support surface 103 to control a voltage on the top surface 109T of the edge ring 109.

In some embodiments, generating the prescribed voltage waveform in the operation 1501 includes generating a temporally constant voltage magnitude, generating a temporally varying voltage, and combining the temporally constant voltage magnitude and the temporally varying voltage to form the prescribed voltage waveform on the bias voltage supply node 905. In some embodiments, the temporally varying voltage varies substantially linearly as a function of time.

In some embodiments, the prescribed voltage waveform generated in the operation 1501 is a pulsed voltage waveform defined as an ongoing series of pulse cycles, where each pulse cycle includes an on-duration in which the pulsed voltage waveform has a negative voltage and an off-duration in which the pulsed voltage waveform has a positive voltage. In some embodiments, the method includes supplying a radiofrequency signal to the bias voltage supply node 905 in conjunction with generating the prescribed voltage waveform on the bias voltage supply node 905 in the operation 1501.

In some embodiments, the method includes using the series capacitor 923 and the shunt capacitor 925 within the electrical circuit 917 extending from the bias voltage supply node 905 to the edge ring electrode 113 to generate the second version of the prescribed voltage waveform that is transmitted to the edge ring electrode 113. In some embodiments, the method includes controlling the shunt capacitor 925 to establish a prescribed voltage differential between the top surface 105T of the substrate 105 and the top surface 109T of the edge ring 109 during the on-duration of each pulse cycle of the pulsed voltage waveform that corresponds to the prescribed voltage waveform generated in the operation 1501. In some embodiments, the method includes controlling the series capacitor 923 to maintain the prescribed voltage differential between the top surface 105T of the substrate 105 and the top surface 109T of the edge ring 109 at a substantially constant level over the on-duration of each pulse cycle of the pulsed voltage waveform that corresponds to the prescribed voltage waveform generated in the operation 1501. In some embodiments, the method includes controlling the series capacitor 923 to change a voltage on the top surface 109T of the edge ring 109 as a function of time to compensate for an electrical discharge on the top surface of the edge ring 109 as a function of time.

In some embodiments, the method includes using the first series capacitor 919 and the first shunt capacitor 921 within the first electrical circuit 915 extending from the bias voltage supply node 905 to the primary bias electrode 111 to generate the first version of the prescribed voltage waveform that is transmitted to the primary bias electrode 111. In some embodiments, the method also includes using the second series capacitor 923 and the second shunt capacitor 925 within the second electrical circuit 917 extending from the bias voltage supply node 905 to the edge ring electrode 113 to generate the second version of the prescribed voltage waveform that is transmitted to the edge ring electrode 113. In some embodiments, the method includes controlling the first shunt capacitor 921 and the second shunt capacitor 925 to establish a prescribed voltage differential between the top surface 105T of the substrate 105 and the top surface 109T of the edge ring 109 during the on-duration of each pulse cycle of the pulsed voltage waveform that corresponds to the prescribed voltage waveform generated in the operation 1501. In some embodiments, the method includes controlling the first series capacitor 919 and the second series capacitor 923 to maintain the prescribed voltage differential between the top surface 105T of the substrate 105 and the top surface 109T of the edge ring 109 at a substantially constant level over the on-duration of each pulse cycle of the pulsed voltage waveform that corresponds to the prescribed voltage waveform generated in the operation 1501.

The various embodiments described herein may be practiced in conjunction with various computer system configurations including hand-held hardware units, microprocessor systems, microprocessor-based or programmable consumer electronics, minicomputers, mainframe computers and the like. The various embodiments described herein can also be practiced in conjunction with distributed computing environments where tasks are performed by remote processing hardware units that are linked through a computer network. It should also be understood that the various embodiments disclosed herein include performance of various computer-implemented operations involving data stored in computer systems. These computer-implemented operations are those that manipulate physical quantities. In various embodiments, the computer-implemented operations are performed by either a general purpose computer or a special purpose computer. In some embodiments, the computer-implemented operations are performed by a selectively activated computer, and/or are directed by one or more computer programs stored in a computer memory or obtained over a computer network. When computer programs and/or digital data is obtained over the computer network, the digital data may be processed by other computers on the computer network, e.g., a cloud of computing resources. The computer programs and digital data are stored as computer-readable code on a non-transitory computer-readable medium. The non-transitory computer-readable medium is any data storage hardware unit, e.g., a memory device, etc., that stores data, which is thereafter readable by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), digital video/versatile disc (DVD), magnetic tapes, and other optical and non-optical data storage hardware units. In some embodiments, the computer programs and/or digital data are distributed among multiple computer-readable media located in different computer systems within a network of coupled computer systems, such that the computer programs and/or digital data is executed and/or stored in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A bias voltage supply system, comprising:
a primary bias electrode disposed below a substrate support surface, the primary bias electrode configured to control a voltage on a top surface of a substrate on the substrate support surface;
an edge ring electrode disposed within an edge ring that circumscribes the substrate support surface, the edge ring electrode configured to control a voltage on a top surface of the edge ring;
a voltage supply system configured to generate a prescribed voltage waveform as a function of time on a bias voltage supply node;
a first branch circuit electrically connected between the bias voltage supply node and the primary bias electrode; and
a second branch circuit electrically connected between the bias voltage supply node and the edge ring electrode, the second branch circuit including a series capacitor and a shunt capacitor.

2. The bias voltage supply system as recited in claim 1, wherein the voltage supply system includes a first voltage supply and a second voltage supply, the first voltage supply configured to generate a temporally constant voltage magnitude, the second voltage supply configured to generate a temporally varying voltage, wherein the temporally constant voltage magnitude and the temporally varying voltage combine to form the prescribed voltage waveform.

3. The bias voltage supply system as recited in claim 2, wherein the temporally varying voltage varies substantially linearly as a function of time.

4. The bias voltage supply system as recited in claim 2, wherein the first voltage supply is a first direct current voltage supply, and the second voltage supply is a second direct current voltage supply.

5. The bias voltage supply system as recited in claim 1, wherein the prescribed voltage waveform is a pulsed voltage waveform defined as an ongoing series of pulse cycles, wherein each pulse cycle includes an on-duration in which the pulsed voltage waveform has a negative voltage and an off-duration in which the pulsed voltage waveform has a positive voltage.

6. The bias voltage supply system as recited in claim 5, wherein the shunt capacitor is set to establish a prescribed voltage differential between the top surface of the substrate and the top surface of the edge ring during the on-duration of each pulse cycle of the pulsed voltage waveform.

7. The bias voltage supply system as recited in claim 6, wherein the series capacitor is set to maintain the prescribed voltage differential between the top surface of the substrate and the top surface of the edge ring at a substantially constant level over the on-duration of each pulse cycle of the pulsed voltage waveform.

8. The bias voltage supply system as recited in claim 7, wherein the series capacitor is set to change a voltage on the top surface of the substrate as a function of time to compensate for an electrical discharge on the top surface of the substrate as a function of time.

9. The bias voltage supply system as recited in claim 1, wherein each of the series capacitor and the shunt capacitor is a respective independently controllable variable capacitor.

10. The bias voltage supply system as recited in claim 1, further comprising:
a radiofrequency power supply electrically connected to supply a radiofrequency signal to the bias voltage supply node in conjunction with generation of the prescribed voltage waveform by the voltage supply system.

11. The bias voltage supply system as recited in claim 1, wherein said series capacitor is a first series capacitor, and said shunt capacitor is a first shunt capacitor, the first branch circuit including a second series capacitor and a second shunt capacitor.

12. The bias voltage supply system as recited in claim 11, wherein the prescribed voltage waveform is pulsed voltage waveform defined as an ongoing series of pulse cycles, wherein each pulse cycle includes an on-duration in which the pulsed voltage waveform has a negative voltage and an off-duration in which the pulsed voltage waveform has a positive voltage, and wherein the first shunt capacitor and the second shunt capacitor are collectively set to establish a prescribed voltage differential between the top surface of the substrate and the top surface of the edge ring during the on-duration of each pulse cycle of the pulsed voltage waveform.

13. The bias voltage supply system as recited in claim 12, wherein the first series capacitor and the second series capacitor are collectively set to maintain the prescribed voltage differential between the top surface of the substrate and the top surface of the edge ring at a substantially constant level over the on-duration of each pulse cycle of the pulsed voltage waveform.

14. The bias voltage supply system as recited in claim 11, wherein the first series capacitor is a first variable capacitor, the first shunt capacitor is second variable capacitor, the second series capacitor is a third variable capacitor, the second shunt capacitor is a fourth variable capacitor, and wherein the first, second, third, and fourth variable capacitors are independently controllable with respect to each other.

15. The bias voltage supply system as recited in claim 11, further comprising:
a radiofrequency power supply electrically connected to supply a radiofrequency signal to the bias voltage supply node in conjunction with generation of the prescribed voltage waveform by the voltage supply system.

16. A bias voltage supply system, comprising:
a primary bias electrode disposed below a substrate support surface, the primary bias electrode configured to control a voltage on a top surface of a substrate on the substrate support surface;
an edge ring electrode disposed within an edge ring that circumscribes the substrate support surface, the edge ring electrode configured to control a voltage on a top surface of the edge ring;
a first voltage supply system configured to generate a first prescribed voltage waveform as a function of time on the primary bias electrode, wherein the first voltage supply system includes a first voltage supply and a second voltage supply, the first voltage supply configured to generate a first temporally constant voltage magnitude, the second voltage supply configured to generate a first temporally varying voltage, wherein the first temporally constant voltage magnitude and the first temporally varying voltage combine to form the first prescribed voltage waveform; and
a second voltage supply system configured to generate a second prescribed voltage waveform as a function of time on the edge ring electrode, wherein the second voltage supply system includes a third voltage supply and a fourth voltage supply, the third voltage supply configured to generate a second temporally constant voltage magnitude, the fourth voltage supply configured to generate a second temporally varying voltage, wherein the second temporally constant voltage magnitude and the second temporally varying voltage combine to form the second prescribed voltage waveform.

17. The bias voltage supply system as recited in claim 16, wherein the first prescribed voltage waveform is a first pulsed voltage waveform defined as a first ongoing series of pulse cycles in which each pulse cycle includes an on-duration in which the first pulsed voltage waveform has a negative voltage and an off-duration in which the first pulsed voltage waveform has a positive voltage,
wherein the second prescribed voltage waveform is a second pulsed voltage waveform defined as a second ongoing series of pulse cycles in which each pulse cycle includes an on-duration in which the second pulsed voltage waveform has a negative voltage and an off-duration in which the second pulsed voltage waveform has a positive voltage, and
wherein the first pulsed voltage waveform and the second pulsed voltage waveform are synchronized.

18. The bias voltage supply system as recited in claim 16, further comprising:
a radiofrequency power supply electrically connected to supply a radiofrequency signal to both the primary bias electrode and the edge ring electrode in conjunction with generation of the first prescribed voltage waveform by the first voltage supply system and generation of the second prescribed voltage waveform by the second voltage supply system.

19. A method for supplying bias voltage during plasma processing of a substrate, comprising:
generating a prescribed voltage waveform as a function of time on a bias voltage supply node;
transmitting a first version of the prescribed voltage waveform from the bias voltage supply node to a primary bias electrode disposed below a substrate support surface to control a voltage on a top surface of a substrate present on the substrate support surface; and
transmitting a second version of the prescribed voltage waveform to an edge ring electrode disposed within an edge ring that circumscribes the substrate support surface to control a voltage on a top surface of the edge ring.

20. The method as recited in claim 19, wherein generating the prescribed voltage waveform includes generating a temporally constant voltage magnitude, generating a temporally varying voltage, and combining the temporally constant voltage magnitude and the temporally varying voltage to form the prescribed voltage waveform on the bias voltage supply node.

21. The method as recited in claim 20, wherein the temporally varying voltage varies substantially linearly as a function of time.

22. The method as recited in claim 19, wherein the prescribed voltage waveform is a pulsed voltage waveform defined as an ongoing series of pulse cycles, wherein each pulse cycle includes an on-duration in which the pulsed voltage waveform has a negative voltage and an off-duration in which the pulsed voltage waveform has a positive voltage.

23. The method as recited in claim 22, further comprising:
using a series capacitor and a shunt capacitor within an electrical circuit extending from the bias voltage supply node to the edge ring electrode to generate the second version of the prescribed voltage waveform.

24. The method as recited in claim 23, further comprising:
controlling the shunt capacitor to establish a prescribed voltage differential between the top surface of the substrate and the top surface of the edge ring during the on-duration of each pulse cycle of the pulsed voltage waveform.

25. The method as recited in claim 24, further comprising:
controlling the series capacitor to maintain the prescribed voltage differential between the top surface of the substrate and the top surface of the edge ring at a substantially constant level over the on-duration of each pulse cycle of the pulsed voltage waveform.

26. The method as recited in claim 25, further comprising:
controlling the series capacitor to change a voltage on the top surface of the edge ring as a function of time to compensate for an electrical discharge on the top surface of the edge ring as a function of time.

27. The method as recited in claim 22, further comprising:
using a first series capacitor and a first shunt capacitor within a first electrical circuit extending from the bias voltage supply node to the primary bias electrode to generate the first version of the prescribed voltage waveform; and
using a second series capacitor and a second shunt capacitor within a second electrical circuit extending from the bias voltage supply node to the edge ring electrode to generate the second version of the prescribed voltage waveform.

28. The method as recited in claim 27, further comprising:
controlling the first shunt capacitor and the second shunt capacitor to establish a prescribed voltage differential between the top surface of the substrate and the top surface of the edge ring during the on-duration of each pulse cycle of the pulsed voltage waveform.

29. The method as recited in claim 28, further comprising:
controlling the first series capacitor and the second series capacitor to maintain the prescribed voltage differential between the top surface of the substrate and the top surface of the edge ring at a substantially constant level over the on-duration of each pulse cycle of the pulsed voltage waveform.

30. The method as recited in claim 19, further comprising:
supplying a radiofrequency signal to the bias voltage supply node in conjunction with generating the prescribed voltage waveform on the bias voltage supply node.
